(19) United States
(12) Patent Application Publication
(10) Pub. No.: US 2016/0261055 A1
(43) Pub. Date: Sep. 8, 2016

(54) INTEGRATED ELECTRICAL ASSEMBLY FOR HOUSING MODULAR UNITS AND RELATED COMPONENTS THEREOF

(71) Applicant: QTRAN, INC., Milford, CT (US)

(72) Inventors: John M. TREMAINE, New Canaan, CT (US); Adrian R. TESCHEMAKER, West Haven, CT (US)

(21) Appl. No.: 15/030,536

(22) PCT Filed: Oct. 20, 2014
(86) PCT No.: PCT/US2014/061294

§ 371 Date: Apr. 19, 2016

Related U.S. Application Data
(60) Provisional application No. 61/893,664, filed on Oct. 21, 2013.
(60) Provisional application No. 62/003,456, filed on May 27, 2014.

(51) Int. Cl. H01R 9/24; H05K 5/06; H05K 5/00; H05K 5/03; H02G 3/08; H02G 3/12

(52) U.S. Cl. CPC H01R 9/2416; H02G 3/081; H02G 3/12; H05K 5/0004; H05K 5/03; H05K 5/061

(57) ABSTRACT

Exemplary embodiments of the present invention are directed to a multi-wire connector that may include a terminal block including a plurality of set screws, in which the plurality of set screws are configured to be loosened and tightened relative to the terminal block, and a housing configured to contain the terminal block, in which the housing includes vents along an upper edge and along a lower edge, and the vents are configured to provide ventilation for the terminal block. The housing may also include two mounting tabs below the terminal block, and the mounting tabs are configured to secure the housing to a base mount.

### CROSS-REFERENCE TO RELATED APPLICATIONS

This application is based on and/or relates to U.S. Provisional Appl. No. 61/893,664 filed Oct. 21, 2013 and U.S. Provisional Appl. No. 62/003,456 filed May 27, 2014, which are both hereby incorporated by reference in their entireties.

### BACKGROUND OF THE INVENTION

1. Field of the Invention

The present invention generally relates to enclosures configured to contain one or more building system related component, and more particularly to an integrated electrical assembly for containing building system related components in one location while providing suitable protection for such components.

Aspects of the present invention also relate to individual electrical components, such as multi-wire connectors and junction boxes.

2. Description of Related Art

Conventional building techniques are well known, and generally require a significant involvement of skilled tradesman, laborers and technicians at specific locations and specific times in order to bring a particular building structure to completion that requires complex coordination. Every variety of building structure includes various components in order to allow for the building structure to be functional and/or habitable. These various components, include but are not limited to, electrical, mechanical, plumbing and waste water management, heating and cooling, informational, emergency and security systems. In conventional building techniques, many of these components must be installed and assembled at each location in which the building structure is constructed, and final testing of the installed systems is costly and time consuming. Furthermore, many of these components may perform related functions, but require specialized personnel for the installation and assembly of such components. In addition, many of these components may require suitable protection from the environments in which the components may be installed. Therefore, it may be desirable to provide a housing structure that is configured to house and contain one or more of the various building structure components, provide for efficient integration and connection of the building structure components between one another and provide for sufficient protection from the environments in which the housing structure and/or building structure components may be installed. Furthermore, it may also be desirable to provide a housing structure that is configured to reduce construction and/or installation time and/or cost associated with the components that may be contained in the housing structure, and to provide a housing structure that can be assembled and have the components contained therein interconnected and/or preconfigured in a controlled environment in order to at least provide for predictability in time and/or cost for installation of such components into the housing and/or building structure, and the ability to test components in a controlled environment prior to installation.

### SUMMARY OF THE INVENTION

The present invention is designed to overcome the above noted limitations that are attendant upon the use of conventional building techniques and materials and, toward this end, it contemplates the provision of a novel integrated electrical assembly in which one or more functional components of a building structure may be housed and/or interconnected to other functional components.

It is an object of the present invention to provide a integrated electrical assembly that provides for a substantially watertight and/or water resistant structure for housing at least one functional component of a building structure, for example an electrical component such as a load center.

It is another object of the present invention to provide an integrated electrical assembly that provides for integration of functional components of a building structure in an efficient manner within the integrated electrical assembly.

It is yet another object of the present invention to provide an integrated electrical assembly that promotes efficient connection between functional components of a building structure within the integrated electrical assembly and between other integrated electrical assemblies.

It is still another object of the present invention to provide a method of integrating functional components of a building structure within an integrated electrical assembly.

It is yet another object of the present invention to provide an integrated electrical assembly containing at least one functional component of a building structure that can efficiently be installed in the building structure.

It is still another object of the present invention to provide an integrated electrical assembly containing at least one function component of a building structure that allows for reduction in construction time and/or cost associated with the construction and/or maintenance of the building structure.

It is yet another object of the present invention to provide an integrated electrical assembly containing at least one functional component of a building structure that provides for at least one modular unit, such as a low voltage power tray, that may be efficiently removed and replaced for repair and/or upgrade as an entire unit, and for connections and/or conduits between the integrated electrical assembly to provide for efficient rewiring of conductors and/or cables running to and from the integrated electrical assembly for purposes of repair and/or upgrade.

It is still another object of the present invention to provide an integrated electrical assembly that contains one or more components that can be tested prior to installation in the integrated electrical assembly in a building structure.

It has now been found that the foregoing and related objects can be readily attained in a housing structure that includes a door and a frame configured to contain at least one functional component of a building structure. The housing structure may also include at least one gasket positioned between the door and the frame, such that a watertight seal is formed between the door and the frame when the door is in a closed position. The housing structure may also include at least one flange extending at least partially around the perimeter of the housing structure. The housing structure may also include a master tub that is configured to receive one or more modular functional components of the building structure. The modular functional components may, for example, be a low voltage power supply unit, a data-com component, an alternative/emergency power component and/or a load center component. The master tub may be configured so as to permit efficient installation of the modular functional components into the housing structure and connection to modular functional components installed in other housing structures within the building structure.

### BRIEF DESCRIPTION OF THE SEVERAL VIEWS OF THE DRAWINGS

For a fuller understanding of the nature and object of the present invention, reference should be had to the following detailed description taken in connection with the accompanying drawings, in which:

FIG. 1 is an exploded view showing how an exemplary embodiment of an integrated electrical assembly according to the present invention may be installed;

FIG. 2 is an isometric view of the exemplary embodiment of the integrated electrical assembly installed on an exemplary wall;

FIG. 2A is an isometric view of the exemplary embodiment of the integrated electrical assembly with a door panel and wall panels installed on and around the integrated electrical assembly;

FIG. 2B is an expanded view of a hinge section of the exemplary embodiment of integrated electrical assembly from FIG. 2;

FIG. 3 is a front view of the exemplary embodiment of the integrated electrical assembly installed on the exemplary wall;

FIG. 3A is a front view of the exemplary embodiment of the integrated electrical assembly with a door panel and wall panels installed on and around the integrated electrical assembly;

FIG. 4 is a cross-sectional view taken along line 4-4 in FIG. 3 of the exemplary embodiment of the integrated electrical assembly installed on the exemplary wall;

FIG. 4A expanded view of the Section from FIG. 4;

FIG. 5 is a right side view of the exemplary embodiment of the integrated electrical assembly installed on the exemplary wall;

FIG. 5A is a right side view of the exemplary embodiment of the integrated electrical assembly with a door panel and wall panels installed on and around the integrated electrical assembly;

FIG. 6 is a left side view of the exemplary embodiment of the integrated electrical assembly installed on the exemplary wall;

FIG. 6A is a left side view of the exemplary embodiment of the integrated electrical assembly with a door panel and wall panels installed on and around the integrated electrical assembly;

FIG. 6B is an expanded view of Section B from FIG. 6A;

FIG. 6C is an expanded view of Section C from FIG. 6A;

FIG. 7 is a bottom plan view of the exemplary embodiment of the integrated electrical assembly installed on the exemplary wall;

FIG. 8 is a top plan view of the exemplary embodiment of the integrated electrical assembly installed on the exemplary wall;

FIG. 9 is a front view of the exemplary embodiment of the integrated electrical assembly installed on the exemplary wall with a door of the integrated electrical assembly in an open position;

FIG. 10 is an isometric view of the exemplary embodiment of the integrated electrical assembly installed on the exemplary wall with the door of the integrated electrical assembly in an open position;

FIG. 11 is a right side view of the exemplary embodiment of the integrated electrical assembly installed on the exemplary wall with the door of the integrated electrical assembly in an open position;

FIG. 12 is a top view of the exemplary embodiment of the integrated electrical assembly installed on the exemplary wall showing the range of motion of the door of the integrated electrical assembly;

FIG. 13 is a rear view of the exemplary embodiment of the integrated electrical assembly installed on the exemplary wall;

FIG. 13A is an expanded view of Section A from FIG. 13 of a component of the exemplary embodiment of the integrated electrical assembly installed on the exemplary wall;

FIG. 13B is an exploded view of an exemplary feed enclosure and template plate that may be used with exemplary embodiments of the integrated electrical assembly according to the present invention;

FIG. 14 is a rear view of the exemplary embodiment of the integrated electrical assembly installed on the exemplary wall with riser pipes removed for clarity;

FIG. 14A is a reverse expanded view of Section A from FIG. 14 of a component of the exemplary embodiment of the integrated electrical assembly installed on the exemplary wall;

FIG. 14B is an expanded view of Section B from FIG. 14 of a component of the exemplary embodiment of the integrated electrical assembly installed on the exemplary wall;

FIG. 14C is a rear view of the exemplary embodiment of the integrated electrical assembly installed on the exemplary wall;

FIG. 14D is a reverse expanded view of FIG. 14C;

FIG. 14E is an isometric top view of the exemplary embodiment of the integrated electrical assembly installed on the exemplary wall;

FIG. 15 is an isometric front view of the exemplary embodiment of the integrated electrical assembly installed on an exemplary wall;

FIG. 16 is an isometric back view of the exemplary embodiment of the integrated electrical assembly installed on the exemplary wall;

FIG. 17 is a back view of the exemplary embodiment of the integrated electrical assembly installed on the exemplary wall;

FIG. 18 is a left side view of the exemplary embodiment of the integrated electrical assembly installed on the exemplary wall;

FIG. 19 is a front view of the exemplary embodiment of the integrated electrical assembly installed on the exemplary wall;

FIG. 20 is a front view of the exemplary embodiment of the integrated electrical assembly configured for installation within a wall;

FIG. 21 is a left side view of the exemplary embodiment of the integrated electrical assembly configured for installation within a wall;

FIG. 22 is a back view of the exemplary embodiment of the integrated electrical assembly configured for installation within a wall;

FIG. 23 is an isometric back view of the exemplary embodiment of the integrated electrical assembly configured for installation within a wall;

FIG. 23A is an expanded view of the exemplary embodiment of the integrated electrical assembly of FIG. 23 without a back panel;

FIG. 24 is an isometric front view of the exemplary embodiment of the integrated electrical assembly configured for installation within a wall;

FIG. 25 is an isometric front view of an exemplary master tub that may be used with exemplary embodiments of the integrated electrical assembly according to aspects of the present invention;

FIG. 26 is a left side view of the exemplary master tub that may be used with exemplary embodiments of the integrated electrical assembly according to aspects of the present invention;

FIG. 27 is a bottom view of the exemplary master tub that may be used with exemplary embodiments of the integrated electrical assembly according to aspects of the present invention;

FIG. 28 is a front view of the exemplary master tub that may be used with exemplary embodiments of the integrated electrical assembly according to aspects of the present invention;

FIG. 29 is a top view of the exemplary master tub that may be used with exemplary embodiments of the integrated electrical assembly according to aspects of the present invention;

FIG. 30 is an isometric front view of the exemplary master tub with exemplary components installed therein;

FIG. 31 is a right side view of the exemplary master tub with exemplary components installed therein;

FIG. 32 is a front view of the exemplary master tub with exemplary components installed therein;

FIG. 33 is a bottom view of the exemplary master tub with exemplary components installed therein;

FIG. 34 is a top plan view of the exemplary master tub with exemplary components installed therein;

FIG. 35 is an exploded view isometric view of how the exemplary components may be arranged within the exemplary master tub according to aspects of the present invention;

FIG. 36 is a front view of an exemplary low voltage power supply unit that may be used with exemplary embodiments of the integrated electrical assembly according to aspects of the present invention;

FIG. 37 is a side view of the exemplary low voltage power supply unit that may be used with exemplary embodiments of the integrated electrical assembly according to aspects of the present invention;

FIG. 38 is a bottom plan view of the exemplary low voltage power supply unit that may be used with exemplary embodiments of the integrated electrical assembly according to aspects of the present invention;

FIG. 39 is a front isometric view of the exemplary low voltage power supply unit that may be used with exemplary embodiments of the integrated electrical assembly according to aspects of the present invention;

FIG. 40 is a top plan view of the exemplary low voltage power supply unit that may be used with exemplary embodiments of the integrated electrical assembly according to aspects of the present invention;

FIG. 41 is an exploded isometric view of the exemplary low voltage power supply unit that may be used with exemplary embodiments of the integrated electrical assembly according to aspects of the present invention;

FIG. 42 is a front view of the exemplary low voltage power supply unit that may be used with exemplary embodiments of the integrated electrical assembly according to aspects of the present invention with a front panel removed;

FIG. 43 is a front isometric view of the exemplary low voltage power supply unit that may be used with exemplary embodiments of the integrated electrical assembly according to aspects of the present invention with the front panel removed;

FIG. 43A is a front isometric view of another exemplary low voltage power supply unit that may be used with exemplary embodiments of the integrated electrical assembly according to aspects of the present invention with its control compartment and connection compartment in open positions;

FIG. 44 is a front isometric view of an exemplary data-com component that may be used with exemplary embodiments of the integrated electrical assembly according to aspects of the present invention;

FIG. 44A is a top plan view of the exemplary data-com component that may be used with exemplary embodiments of the integrated electrical assembly according to aspects of the present invention;

FIG. 44B is a front view of the exemplary data-com component that may be used with exemplary embodiments of the integrated electrical assembly according to aspects of the present invention;

FIG. 44C is a bottom plan view of the exemplary data-com component that may be used with exemplary embodiments of the integrated electrical assembly according to aspects of the present invention;

FIG. 44D is a side view of the exemplary data-com component that may be used with exemplary embodiments of the integrated electrical assembly according to aspects of the present invention;

FIG. 45 a front isometric view of the exemplary data-com component that may be used with exemplary embodiments of the integrated electrical assembly according to aspects of the present invention with a door open;

FIG. 46 is a front isometric view of the exemplary data-com component that may be used with exemplary embodiments of the integrated electrical assembly according to aspects of the present invention with the door open and a panel partially removed;

FIG. 47 is a front view of the exemplary data-com component that may be used with exemplary embodiments of the integrated electrical assembly according to aspects of the present invention with the door open;

FIG. 48 is a front isometric view of an exemplary alternative power unit that may be used with exemplary embodiments of the integrated electrical assembly according to aspects of the present invention;

FIG. 48A is a front isometric view of an exemplary alternative power unit that may be used with exemplary embodiments of the integrated electrical assembly according to aspects of the present invention with the cover removed;

FIG. 49 is a bottom plan view of the exemplary alternative power unit that may be used with exemplary embodiments of the integrated electrical assembly according to aspects of the present invention;

FIG. 50A is a front view of the exemplary alternative power unit that may be used with exemplary embodiments of the integrated electrical assembly according to aspects of the present invention;

FIG. 50B is a front view of the exemplary alternative power unit that may be used with exemplary embodiments of the integrated electrical assembly according to aspects of the present invention with an exemplary cover removed;

FIG. 51 is a side view of the exemplary alternative power unit that may be used with exemplary embodiments of the integrated electrical assembly according to aspects of the present invention;

FIG. 52 is a top isometric view of an exemplary load center that may be used with exemplary embodiments of the integrated electrical assembly according to aspects of the present invention;

FIG. 53 is a partially exploded front isometric view of the exemplary load center that may be used with exemplary embodiments of the integrated electrical assembly according to aspects of the present invention;

FIG. 54 is an exploded isometric front view of the exemplary load center that may be used with exemplary embodiments of the integrated electrical assembly according to aspects of the present invention;

FIG. 55 is a cross-sectional view taken along line 55-55 in FIG. 52 of the exemplary load center that may be used with exemplary embodiments of the integrated electrical assembly according to aspects of the present invention;

FIG. 56 is a front view of the exemplary load center that may be used with exemplary embodiments of the integrated electrical assembly according to aspects of the present invention with a door in an open position;

FIG. 57 a front view of another exemplary integrated electrical assembly according to the present invention;

FIG. 58 is a side view of an exemplary master tub that may be used with the other exemplary integrated electrical assembly according to the present invention;

FIG. 59 is a front isometric view of the exemplary master tub with exemplary components that may be used with the other exemplary integrated electrical assembly according to the present invention;

FIG. 60 is a bottom plan view of the other exemplary integrated electrical assembly according to the present invention;

FIG. 61 is a front view of the other exemplary integrated electrical assembly according to the present invention with a front panel removed;

FIG. 62 is a top plan view of the other exemplary integrated electrical assembly according to the present invention;

FIG. 63 is a front view of another exemplary low voltage power supply unit that may be used with exemplary embodiments of the integrated electrical assembly according to aspects of the present invention or may be provided as a standalone unit;

FIG. 64 is a front view of the other exemplary low voltage power supply unit that may be used with exemplary embodiments of the integrated electrical assembly according to aspects of the present invention with a front panel removed;

FIG. 65 is a side view of the other exemplary low voltage power supply unit that may be used with exemplary embodiments of the integrated electrical assembly according to aspects of the present invention or may be provided as a standalone unit;

FIG. 66 is a front isometric view of the other exemplary low voltage power supply unit that may be used with exemplary embodiments of the integrated electrical assembly according to aspects of the present invention or may be provided as a standalone unit;

FIG. 67 is a back isometric view of the other exemplary low voltage power supply unit that may be used with exemplary embodiments of the integrated electrical assembly according to aspects of the present invention or may be provided as a standalone unit;

FIG. 68 is a front view of yet another exemplary low voltage power supply unit that may be used with exemplary embodiments of the integrated electrical assembly according to aspects of the present invention with a front panel removed;

FIG. 69 is a side view of the other exemplary low voltage power supply unit that may be used with exemplary embodiments of the integrated electrical assembly according to aspects of the present invention or may be provided as a standalone unit;

FIG. 70 is a front isometric view of the other exemplary low voltage power supply unit that may be used with exemplary embodiments of the integrated electrical assembly according to aspects of the present invention or may be provided as a standalone unit;

FIG. 71 is a generalized schematic view of exemplary electrical connections between an electrical service line and one or more integrated electrical assemblies;

FIG. 72 is a generalized schematic view of exemplary electrical connections between exemplary components of the exemplary embodiments of the integrated electrical assembly according to the present invention;

FIG. 73 is an isometric view of an exemplary multi-wire connector that may be used with the integrated electrical assembly according to the present invention;

FIG. 74 is an exploded view of the exemplary multi-wire connector that may be used with the integrated electrical assembly according to the present invention;

FIG. 75 is a front view of the exemplary multi-wire connector that may be used with the integrated electrical assembly according to the present invention;

FIG. 75A is a front view of the exemplary multi-wire connector without a base mount that may be used with the integrated electrical assembly according to the present invention;

FIG. 76 is a side view of the exemplary multi-wire connector that may be used with the integrated electrical assembly according to the present invention;

FIG. 76A is a side view of the exemplary multi-wire connector without a base mount that may be used with the integrated electrical assembly according to the present invention;

FIGS. 76B and 76C are a side view of the exemplary multi-wire connector showing how the multi-wire connector may be installed on the base mount;

FIG. 77 is a top plan view of the exemplary multi-wire connector that may be used with the integrated electrical assembly according to the present invention;

FIG. 77A is a top plan view of the exemplary multi-wire connector without a base mount that may be used with the integrated electrical assembly according to the present invention;

FIG. 78 is an isometric front view of the exemplary multi-wire connector that may be used with the integrated electrical assembly according to the present invention;

FIG. 78A is an isometric front view of the exemplary multi-wire connector without a base mount that may be used with the integrated electrical assembly according to the present invention;

FIG. 79 is an isometric back view of the exemplary multi-wire connector without a base mount that may be used with the integrated electrical assembly according to the present invention;

FIG. 79A is an isometric back view of the exemplary multi-wire connector without a base mount that may be used with the integrated electrical assembly according to the present invention;

FIG. 80 is a front view of the exemplary multi-wire connector that may be used with the integrated electrical assembly according to the present invention mounted to an exemplary surface;

FIG. 80A is a front view of the exemplary multi-wire connector without a base mount that may be used with the integrated electrical assembly according to the present invention mounted to an exemplary surface;

FIG. 81 is a side view of the exemplary multi-wire connector that may be used with the integrated electrical assembly according to the present invention mounted to an exemplary surface;

FIG. 81A is a side view of the exemplary multi-wire connector without a base mount that may be used with the integrated electrical assembly according to the present invention mounted to an exemplary surface;

FIG. 82 is a top plan view of the exemplary multi-wire connector that may be used with the integrated electrical assembly according to the present invention;

FIG. 83 is a cross-sectional view taken along line 83-83 in FIG. 82 of the exemplary multi-wire connector that may be used with the integrated electrical assembly according to the present invention;

FIG. 84 is a top view of the exemplary multi-wire connector that may be used with the integrated electrical assembly according to the present invention;

FIG. 85 is a cross-sectional view taken along line 85-85 in FIG. 84 of the exemplary multi-wire connector that may be used with the integrated electrical assembly according to the present invention;

FIG. 86 generalized schematic view of data-com connections between a data-com distribution panel and one or more integrated electrical assemblies;

FIG. 87 is a front isometric view of an exemplary junction box that may be configured for connection to the integrated electrical assembly according to the present invention;

FIG. 87A is a front isometric view of the exemplary junction box without a decorative panel that may be configured for connection to the integrated electrical assembly according to the present invention;

FIG. 88 is an isometric back view of the exemplary junction box that may be configured for connection to the integrated electrical assembly according to the present invention;

FIG. 89 is a front view of the exemplary junction box that may be configured for connection to the integrated electrical assembly according to the present invention;

FIG. 89A is a front view of the exemplary junction box without a decorative panel that may be configured for connection to the integrated electrical assembly according to the present invention;

FIG. 90 is a bottom plan view of the exemplary junction box that may be configured for connection to the integrated electrical assembly according to the present invention;

FIG. 90A is a bottom plan view of the exemplary junction box without a decorative panel that may be configured for connection to the integrated electrical assembly according to the present invention;

FIG. 91 is a side view of the exemplary junction box that may be configured for connection to the integrated electrical assembly according to the present invention;

FIG. 91A is a side view of the exemplary junction box without a decorative panel that may be configured for connection to the integrated electrical assembly according to the present invention;

FIG. 92 is an isometric view of the exemplary junction box for installation in an exemplary wall;

FIG. 93 is a front view of the exemplary junction box installed in the exemplary wall;

FIG. 94 is a cross-sectional view taken along line 94-94 in FIG. 93 of the exemplary junction box installed in the exemplary wall;

FIG. 95 is an exploded view of the exemplary junction box that may be configured for connection to the integrated electrical assembly according to the present invention;

FIG. 96 is an isometric front view of another exemplary junction box that may be configured for connection to the integrated electrical assembly according to the present invention;

FIG. 96A is an isometric view of the other exemplary junction box without a decorative panel that may be configured for connection to the integrated electrical assembly according to the present invention;

FIG. 97 is a side view of the other exemplary junction box that may be configured for connection to the integrated electrical assembly according to the present invention;

FIG. 97A is a side view of the other exemplary junction box without a decorative panel that may be configured for connection to the integrated electrical assembly according to the present invention;

FIG. 98 is a front view of the other exemplary junction box that may be configured for connection to the integrated electrical assembly according to the present invention;

FIG. 98A is a front plan view of the other exemplary junction box without a decorative panel that may be configured for connection to the integrated electrical assembly according to the present invention;

FIG. 99 is a top plan view of the other exemplary junction box that may be configured for connection to the integrated electrical assembly according to the present invention;

FIG. 99A is a top plan view of the other exemplary junction box without a decorative panel that may be configured for connection to the integrated electrical assembly according to the present invention; and

FIG. 100 is an isometric view of the other exemplary junction box showing surface mounted installation of the exemplary junction box.

### DETAILED DESCRIPTION OF THE INVENTION

The present invention now will be described more fully hereinafter with reference to the accompanying figures, in which exemplary embodiments of the invention are shown. The invention may, however, be embodied in many different forms and should not be construed as limited to the embodiments set forth herein. Like reference numerals refer to like elements throughout.

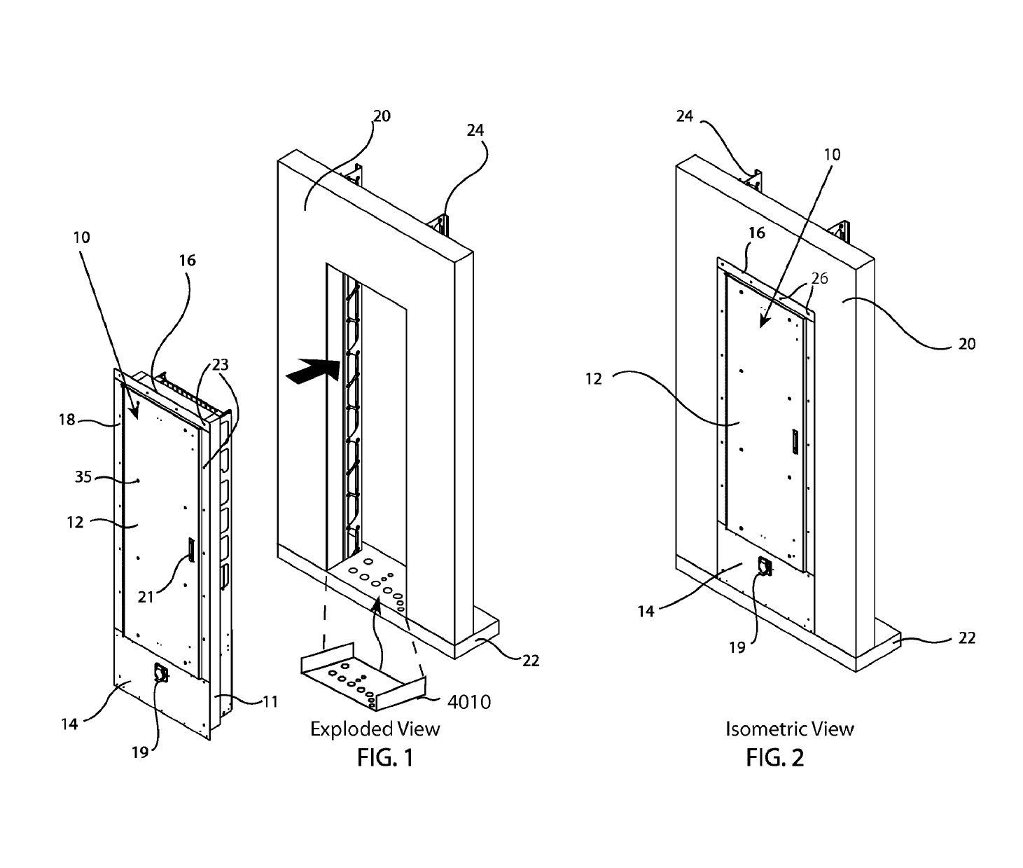

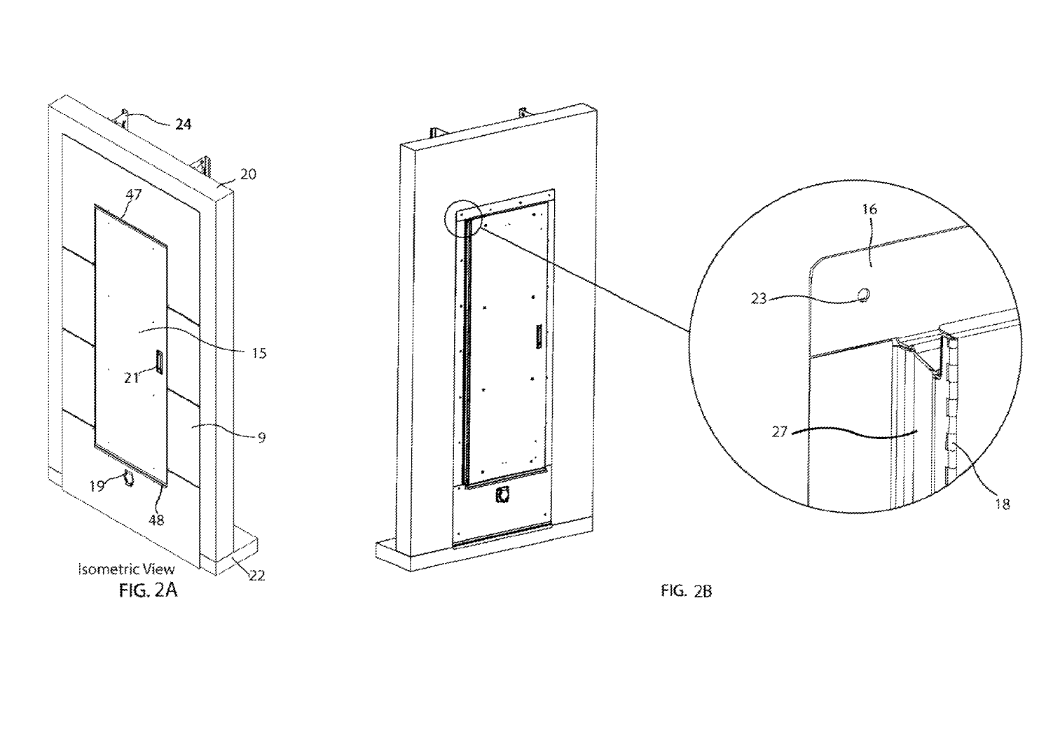

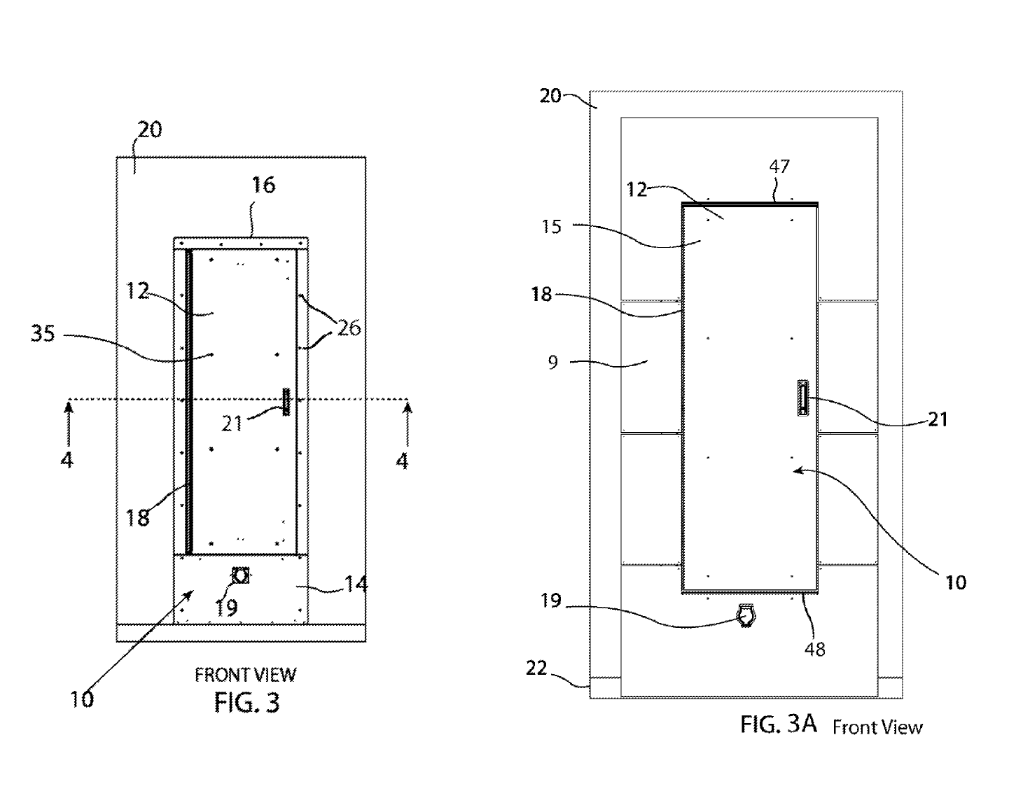

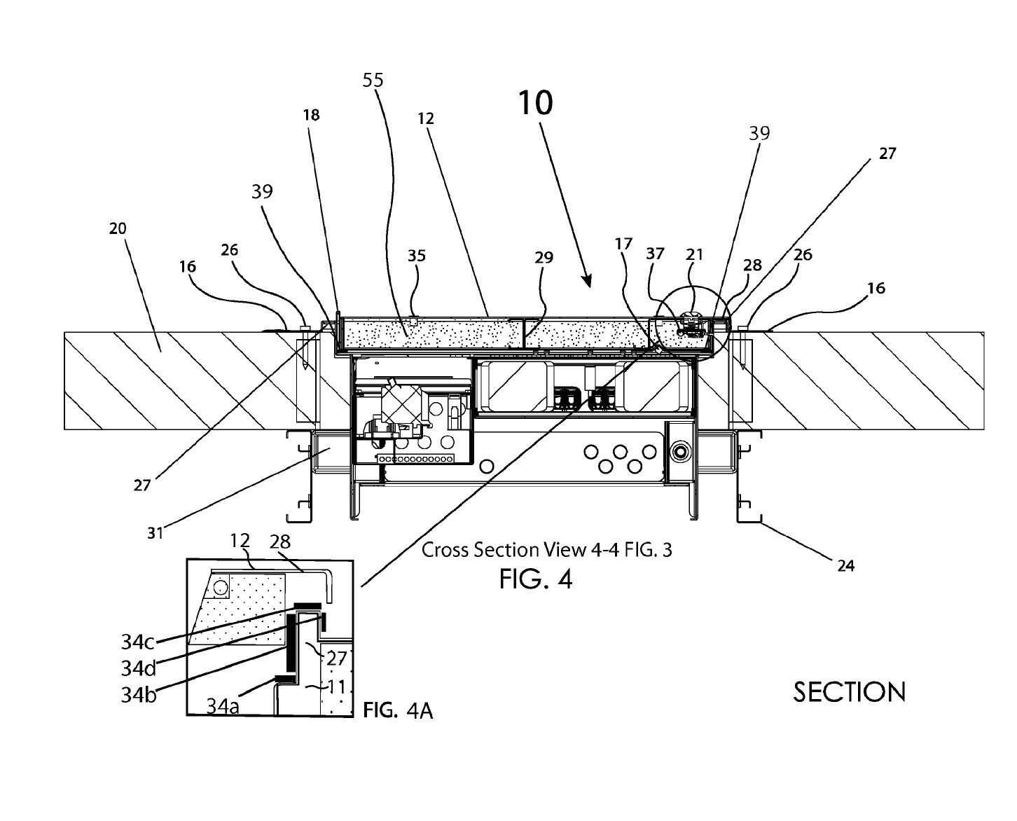

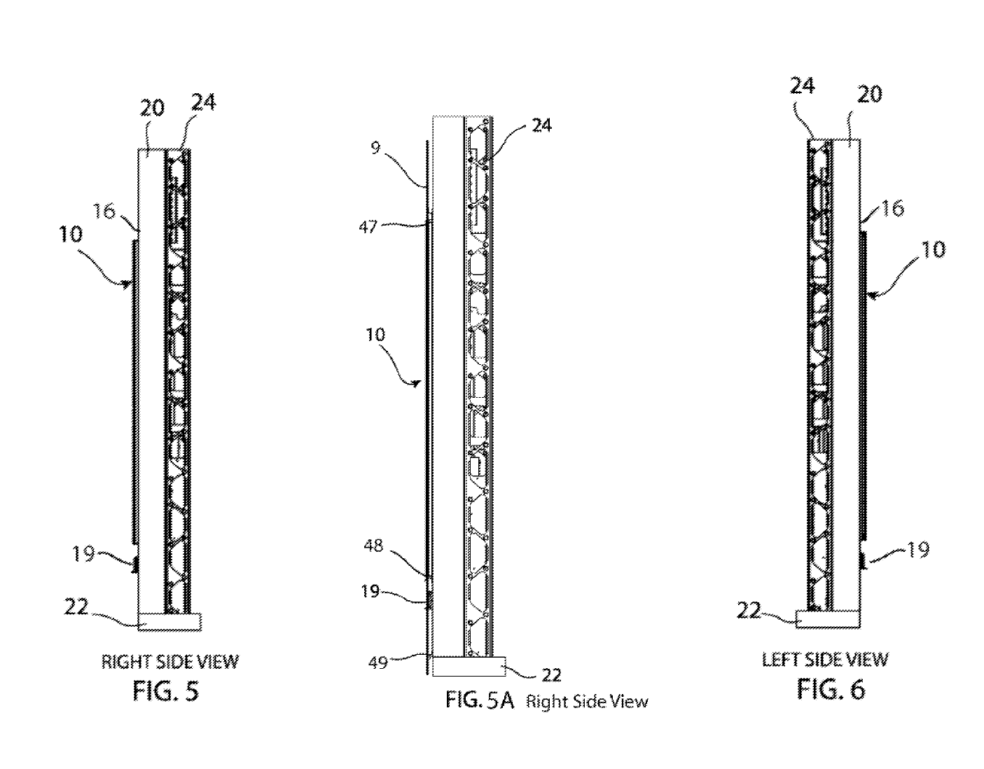

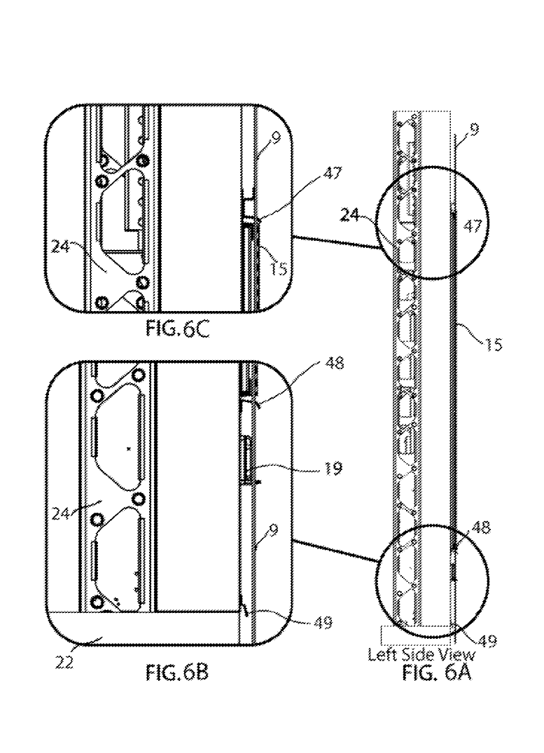

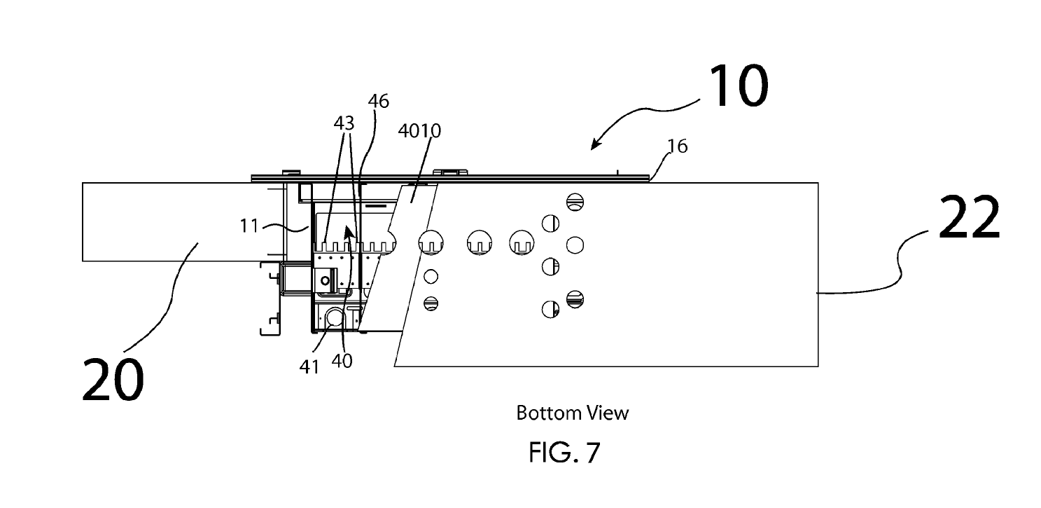

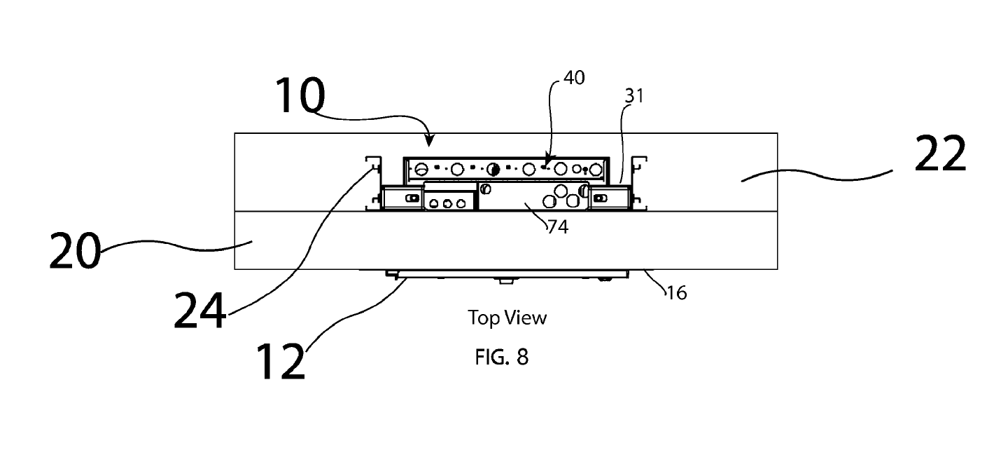

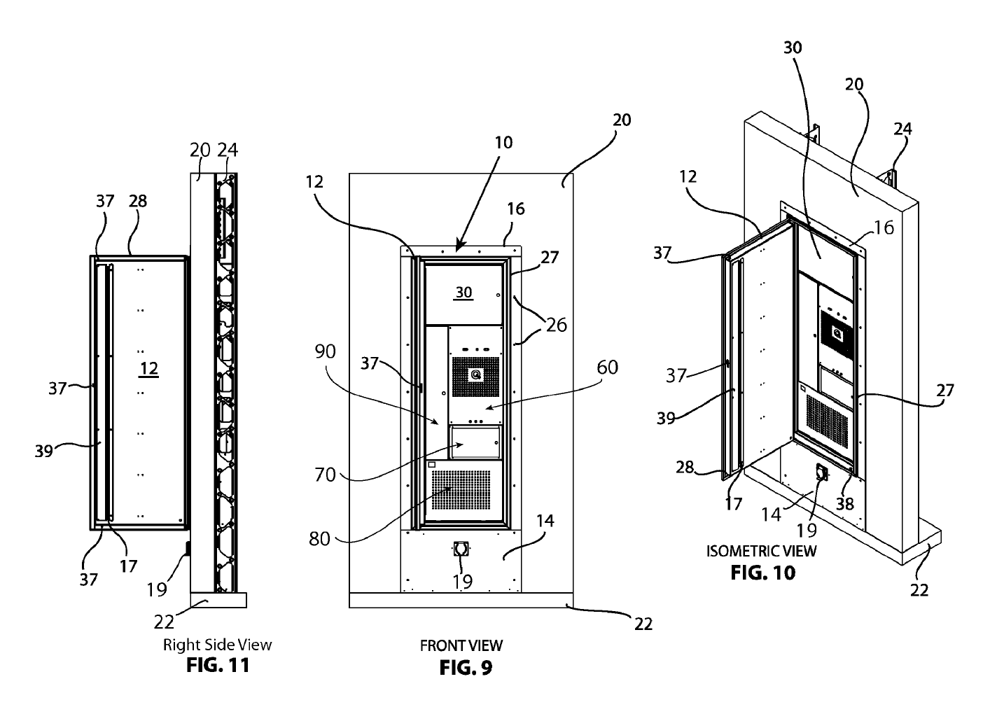

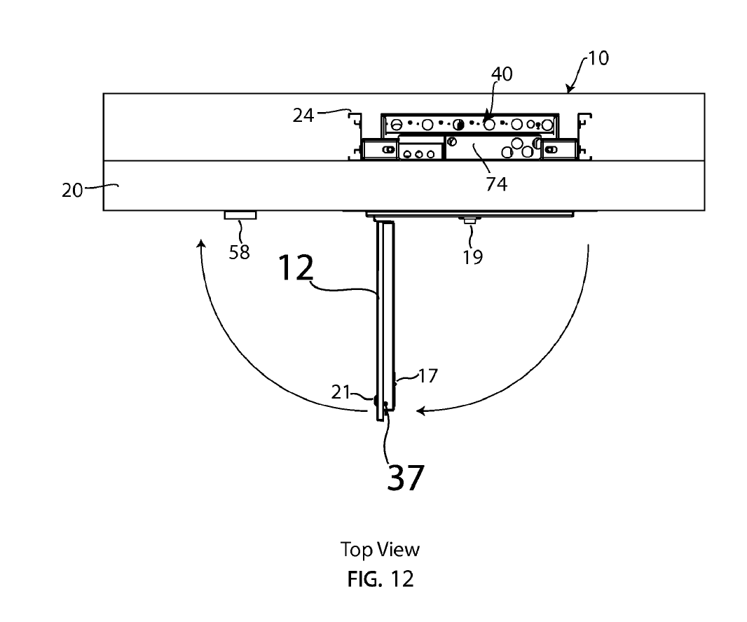

Referring now to FIGS. 1-2, 2B, 3, 4, 5, 6-13, 13A, 14 and 14A-14E, therein illustrated is an exemplary embodiment of an integrated electrical assembly, generally indicated by reference numeral 10, according to the present invention. The integrated electrical assembly 10 may for example be master electrical distribution node for a building structure and/or a subspace (individual unit) within the building structure, such as one or more living units, hospital rooms, retail spaces, flex warehousing and the like, that integrates one or more electrical, lighting and/or data-com systems together. The integrated electrical assembly 10 may also be configured as a slave integrated electrical assembly 10 that receives wiring from the master electrical distribution node. The integrated electrical assembly 10 may include a frame 11, a swing door 12 attached to the frame 11 by a hinge 18 and a mounting flange 16 extending around the periphery of the frame 11. The hinge 18 may be constructed so that it extends over a housing lip 27, as shown in greater detail in FIG. 2B. Furthermore, preferably the hinge 18 may be a continuous piano hinge that may be formed from a non-corrosive or corrosion resistive metal, such as stainless steel. Even more preferably, the hinge 18 may be configured so as to support a heavy durable door and provide for pressure relief and/or reduction from high pressure water sprays/jet, for example from power washings of the building structure, in order to allow the integrated electrical assembly 10 to obtain at least a NEMA 4 listing. The integrated electrical assembly 10 may also include a bottom panel 14 that may contain an outlet 19 with a watertight/water proof cover. For example, the outlet may be a watertight twist lock receptacle, and may preferably be a NEMA 4 rated watertight twist lock receptacle. The swing door 12 of the integrated electrical assembly 10 may contain a door handle 21 for permitting access to and closing of the swing door 12, and the door handle 21 may contain a locking mechanism, such as a keyed tumbler, in order to allow for restricting access to the integrated electrical assembly 10.

The integrated electrical assembly 10 may be configured for installation in an exemplary wall 20, which may be for example an exterior wall. The integrated electrical assembly 10 may be positioned in an opening formed in the wall 20 that may be flanked by one or more wall supports 24 and a floor surface 22 on the bottom of the opening. A template plate 4010 may be placed on the floor surface 22 on the bottom of the opening in order to provide a guide for cables and/or conduits running into the integrated electrical assembly. The wall support 24 may be an industry standard steel stud or a formed metal stud, for example a roll formed and stamped steel stud such as a DELTASTUD available from Steelform Building Products Inc. The floor surface 22 may be any suitable building flooring surface and/or structure, and may be for example concrete. The opening preferably may be slightly larger than the size of the frame 11 of the integrated electrical assembly 10, but smaller than the size of the mounting flange 16 extending around the integrated electrical assembly 10. A bead of a sealant (not shown), such as silicon, polyurethane, acrylic, adhesive, epoxy, may be placed between the mounting flange 16 and the wall 20 so as to provide for a water tight seal between the integrated electrical assembly 10 and the wall 20. In the alternative, a gasket (not shown) may be provided on the mounting flange 16 in order to seal the integrated electrical assembly 10 to the wall 20. The mounting flange 16 of the integrated electrical assembly 10 may include one or more mounting holes 23 to allow one or more fasteners 26, such as nails, screws, bolts, lag screws, lag bolts to secure the integrated electrical assembly 10 to the wall 20. Another sealant (not shown) may be placed over the mounting flange 16 and the fasteners 26, and extend at least partially onto the wall 20 in order to further seal the integrated electrical assembly 10 to the wall 20 in order to prevent water or moisture penetrating between the integrated electrical assembly 10 and the wall 20.

Referring more specifically to FIGS. 4 and 9-12, the integrated electrical assembly 10 may also include the housing lip 27 extending around the inside perimeter of the mounting flange 16, and a corresponding door lip 28 formed in the swing door 12 that is configured to cover the housing lip 27 when the swing door 12 is in a closed position, for example as shown in FIG. 4. The door lip 28 extends around three sides of the swing door 12 so that when the swing door 12 is in a closed position, the door lip 28 extends over and around the housing lip 27 in order to provide for pressure relief and/or reduction from high pressure water sprays/jet in order to allow the integrated electrical assembly 10 to obtain at least a NEMA 4 listing. A door gasket 34a may be placed around the periphery of where the swing door 12 contacts the integrated electrical assembly 10 in order to provide for a watertight seal between the swing door 12 and the integrated electrical assembly 10. As shown for example in FIG. 4A, additional door gaskets 34b, 34c, 34d may also be placed on or around the housing lip 27 to provide additional seals with the door lip 28 when the swing door 12 in a closed position on three sides. Any combination of door gaskets 34a, 34b, 34c, 34d may be used with the present invention. It is understood that the configuration of the door lip 28, the housing lip 27 when the swing door 12 is in a closed position in combination with the hinge 18 on the side of the swing door 12 that does not include the door lip 28 and the one or more of the gaskets 34a, 34b, 34c, 34d are capable of producing a watertight seal for the integrated electrical assembly 10 to obtain at least a NEMA 4 listing. The swing door 12 may also include at least one I-beam 29, or other structural member formed or fabricated within the swing door 12 so as to provide structural rigidity to the swing door 12, and to prevent heat warping of the swing door 12. The space within the swing door 12 may be at least partially filled with insulation 55 so that the integrated electrical assembly 10 is resistive to heat and/or cold transfer from outside the integrated electrical assembly 10 to the components within the integrated electrical assembly. The swing door 12 of the integrated electrical assembly 10 may also include one or more threaded plugs 35 that are configured to threadenly engage with a threaded fastener (not shown) in order to allow items, such as rain and/or decorative door panels 15 (FIGS. 2A, 3A, 5A and 6A-6B), to be secured to the swing door 12 and/or the integrated electrical assembly 10. The threaded plugs 35 may be configured such that the threaded plugs 35 compressed when the threaded fastener is tightened onto the threaded plugs 35 so as to seal the threaded plugs 35 against the swing door 12. The swing door 12 of the integrated electrical assembly 10 may also include a low voltage lighting strip 17, for example an LED strip or similar, that provides illumination to the integrated electrical assembly 10 when the swing door 12 of the integrated electrical assembly 10 is in an open position. The swing door 12 of the integrated electrical assembly 10 may also include one or more latching mechanisms 37, for example a rod, connected to and actuated by the door handle 21, and configured to secure the swing door 12 to the frame 11 when the swing door 12 is in a closed position. Preferably the latching mechanisms 37 may be configured to provide for a three-point closure, in which there is at least one latching mechanism 37 on the top and bottom and at least one side of the swing door 12. The latching mechanisms 37 may engage with corresponding openings 38 in the frame 11 of the integrated electrical assembly 10. The swing door 12 may also include a removable panel 39 in order to permit access to the one or more latching mechanisms 37 and interior components of the door handle 21 for maintenance and/or repair when the swing door 12 is in an open position. It is understood that the swing door 12 may be configured to be opened to 180°, but that the swing door 12 may include mechanisms (not shown) in order to permit the swing door 12 to only open a certain amount so as to prevent accidental damage to nearby objects and/or persons, or may include fixed and/or adjustable stops (not shown) that are configured to hold the swing door 12 open at a particular open position, for example at 90°. A magnet 58 may also be positioned on the wall 20 so as to provide a mechanism for securing the swing door 12 in an approximately 180 degree open position.

Referring now to FIGS. 2A, 3A, 5A and 6A-6C, the swing door 12 of the integrated electrical assembly 10 may include a rain and/or decorative door panel 15 installed thereon as discussed above. The wall 20 on which the integrated electrical assembly 10 has been installed may also include one or more rain and/or decorative wall panels 9 installed thereon. Furthermore, a top rain shield drip edge 47 may be installed on the top edge of the integrated electrical assembly 10 in order to prevent and/or reduce moisture, such as rain, from running down the wall 20 and/or wall panel 9 directly onto the integrated electrical assembly 10. It is understood that the top rain shield drip edge 47 may be installed regardless of whether the door panel 15 and/or wall panels 9 have been installed. A middle rain shield drip edge 48 may also be installed between the swing door 12 and the outlet 19 in order to prevent and/or reduce moisture, such as rain, from running down the wall 20 and/or wall panel 9 directly onto the outlet 19. It is understood that the middle rain shield drip edge 48 may be installed regardless of whether the door panel 15 and/or wall panels 9 have been installed. Furthermore, a bottom rain shield drip edge 49 may be installed below the outlet 19 in order to remove any moisture that may be between the wall 20 and wall panels 9. However, it is understood that the bottom rain shield drip edge 49 may be installed regardless of whether the door panel 15 and/or wall panels 9 have been installed.

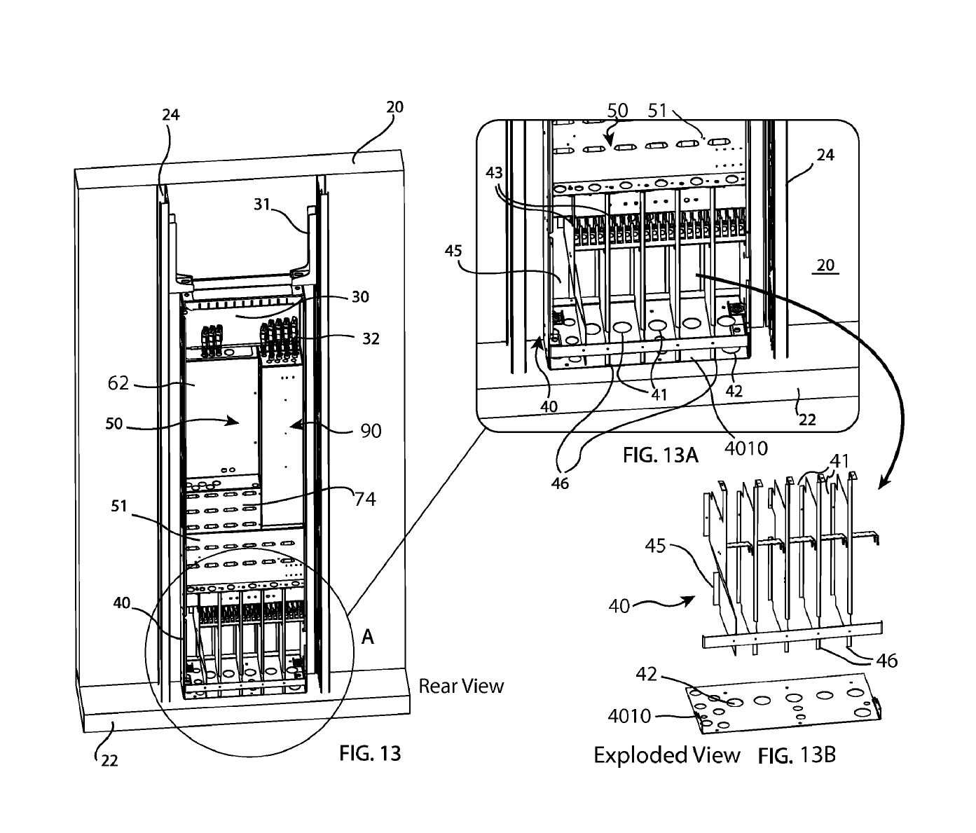

Referring now to FIGS. 13, 13A and 13B, the integrated electrical assembly 10 may also include a master feed enclosure 40 that may be positioned behind the bottom panel 14 and under the master tub 50 of the integrated electrical assembly 10. The master feed enclosure 40 may include one or more high-voltage junction compartments 41, which are each separated by a barrier plate 46. The high-voltage junction compartments 41 are configured to receive wiring (not shown) from an electric service from an electric meter in an electrical room of the building structure through one or more holes/knock-outs 42 positioned on the bottom of the master feed enclosure 40. In this manner, each high-voltage junction compartment 41 receive a separate multi-conductor feed from each electric meter, which can then be further distributed onto additional integrated electrical assemblies 10 as discussed further below. The wiring (not shown) from the electric service may be connected to high voltage distribution cables (not shown), which may be for example 208-240V or the like, such as four copper conductor cables, extending to one or more power distribution blocks 43 within each high-voltage junction compartment 41. The master feed enclosure 40 may also include a data-com junction compartment 45, in which the data-com conduit and/or wiring from a data-com source may be fed into and/or through the integrated electrical assembly 10.

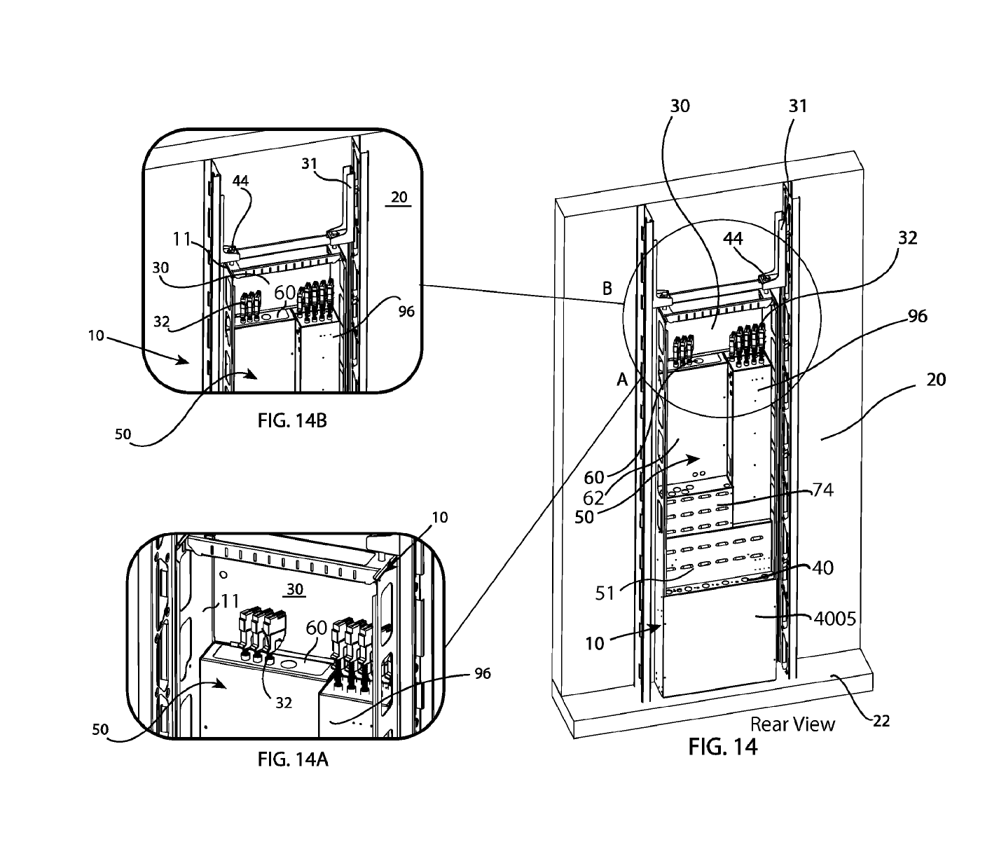

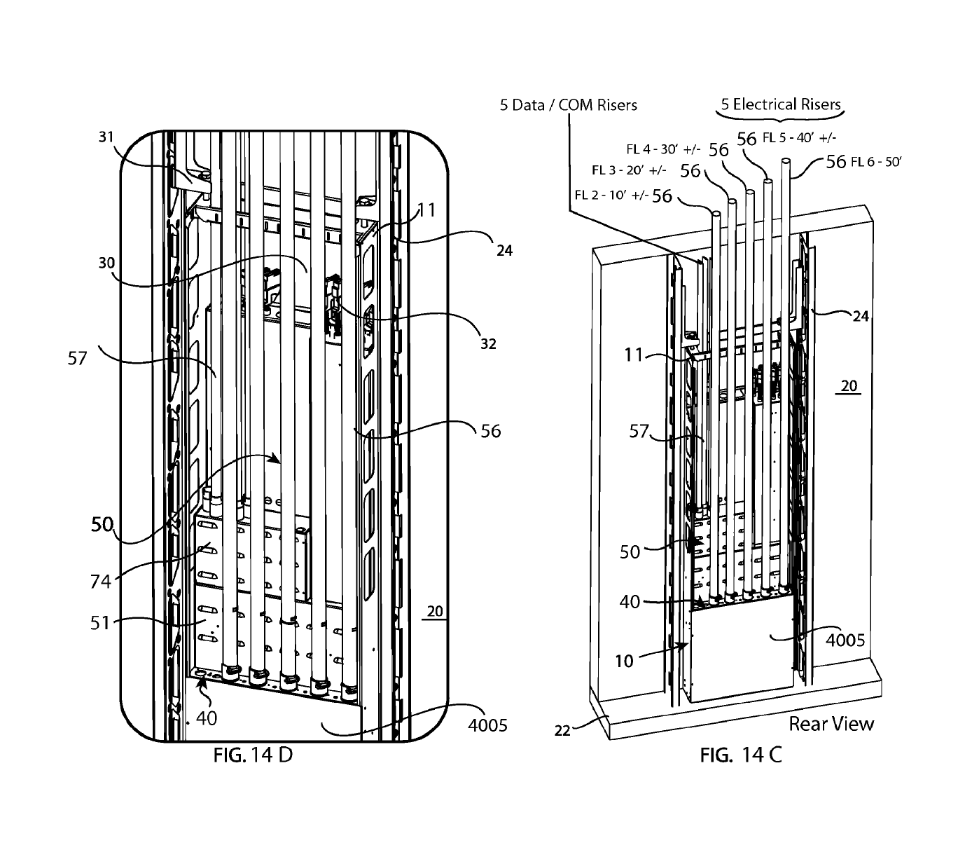

Referring now to FIGS. 14C, 14D and 14E, the master feed enclosure 40 may include an access cover 4005 that is removably attached to the master feed enclosure 40 in order to allow access to the master feed enclosure 40 and the high-voltage junction compartments 41 and data-com junction compartment 45 contained therein. One or more high voltage risers 56 may extend from the master feed enclosure 40 and be configured to connect to another integrated electrical assembly 10 within the building structure. The high voltage risers 56 may be made from flexible, e.g. MC cable, and/or rigid electrical conduit.

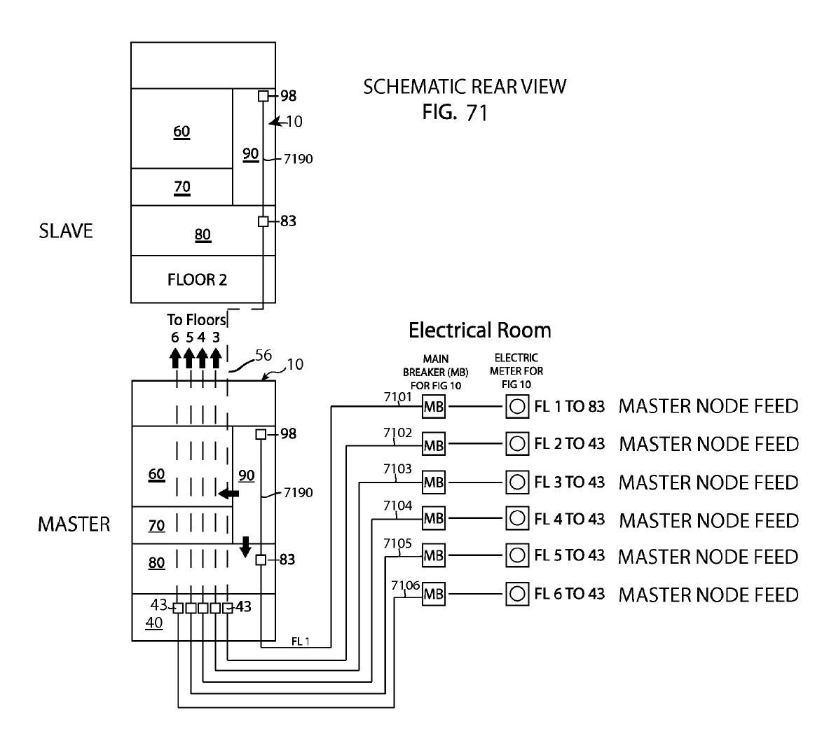

As shown for example in FIG. 71, the integrated electrical assembly 10 may be pre-wired to allow for efficient connection between one or more main breakers (MB) for separate service feeds coming from the electrical room of the building structure. The integrated electrical assembly 10 that is acting as the master electrical distribution node for one or more slave integrated electrical assemblies 10 of the building structure may be connected for its power to an electrical feed line 7101 from a main breaker (MB) by an electrical assembly power distribution block 83 in a main electrical feed unit 80 of the integrated electrical assembly 10. Furthermore, electrical feed lines 7102, 7103, 7104, 7105, 7106 may be run from each main breaker (MB) and connected to separate power distribution blocks 43 within the master feed enclosure 40 of the integrated electrical assembly 10 acting as the electrical distribution node. Each power distribution block 43 has been pre-wired to appropriate wiring in a corresponding high voltage riser 56 so that all that is required for the connection to be made from the corresponding electrical feed line 7102, 7103, 7104, 7105, 7106 to the appropriate power distribution block 43. Since the integrated electrical assembly 10 may be prewired for high voltage electrical distribution by connection of wiring in the high voltage risers 56 to the power distribution blocks 43, the integrated electrical assembly 10 may act as a connection point between the electrical service and additional integrated electrical assemblies 10. For example, FIG. 71 shows the electrical service for floors 2-6 being connected to the integrated electrical assembly 10 and then onto the integrated electrical assemblies 10 for the corresponding floors. It is understood that this process can be repeated as many times a required to complete the wiring of the building structure, for example another integrated electrical assembly 10 can be used as another electrical distribution node for additional integrated electrical assemblies 10 on additional floors of the building structure. In this manner, the amount of time required for installation of wiring and/or runs could be reduced since the integrated electrical assembly 10 provides for a connection node for the high voltage electrical system within the building structure between individual units. This allows for the wiring to be installed in a controlled factory environment, tested and certified.

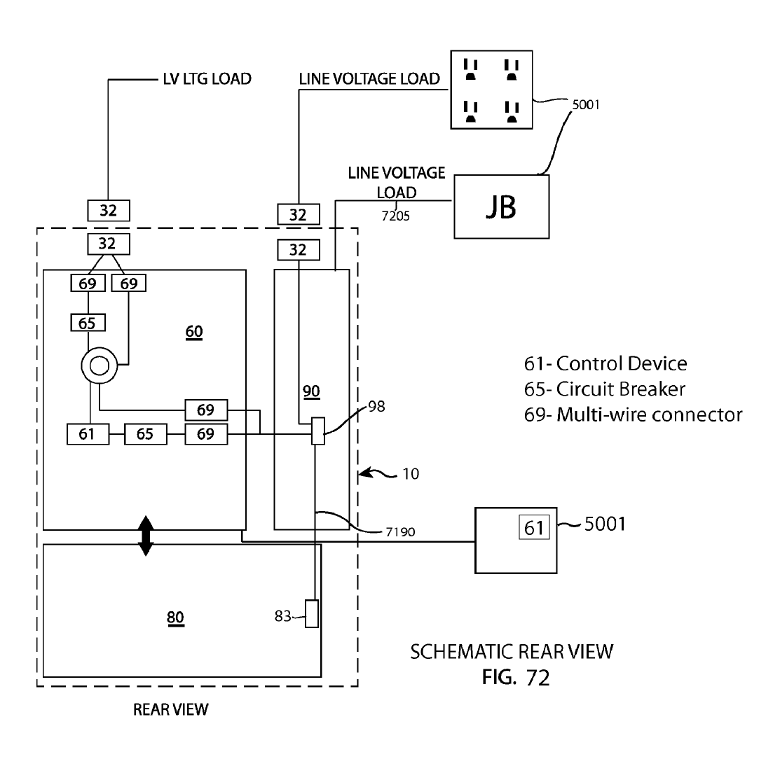

Referring now to FIGS. 13, 14, 14A and 14B, the integrated electrical assembly 10 may also include a master tub 50 positioned therein for containing one or more components that may be located and/or secured in the integrated electrical assembly 10. The integrated electrical assembly 10 may also include an access panel 30 that provides for access to an area located above the master tub 50 in order to permit connections between wiring coming from the integrated electrical assembly 10 to the individual unit to be made. For example, one or more cable connectors 32, as shown in FIGS. 14, 14A and 14B, may be positioned in the area accessible through the access panel 30 in order to allow for the appropriate connections to be made. The one or more cable connectors 32 may be pre-wired whip connectors and/or color coded MC cable connectors. Referring now to FIG. 72 exemplary connections between one or more cable connectors 32 connected to one or more components, for example a low voltage power supply unit 60 and load center 90, and loads within the individual unit of the integrated electrical assembly 10 are shown. Since the cable connectors 32 are used to make the wiring connections between the components of the integrated electrical assembly 10 and loads of the individual unit, for example outlets, lighting, appliances, etc., the wiring from the components of the integrated electrical assembly 10 to the loads of the individual unit may be efficiently made. Furthermore, the one or more components of the integrated electrical assembly 10 can be easily removed and/or replaced for upgrade and/or repair since the components are pre-wired and connected to the loads of the individual unit through the cable connectors 32. This also reduces the amount of labor time required to install the integrated electrical assembly 10, because the connections can be made to prewired loads within the individual unit. The prewired loads of the individual unit could for example be contained in one or more junction boxes 5001 throughout the individual unit, and the junction boxes and related wiring may be prewired into the walls of the individual unit prior to construction of the individual unit within the building structure.

As further shown in FIGS. 13, 14, and 14B the integrated electrical assembly 10 may be secured to the wall supports 24 by one or more support brackets 31. The support brackets 31 are configured so as to be able to be adjustably secured to the wall supports 24 in a manner that allows for adjustment at both the wall support 24 and/or the integrated electrical assembly 10 through use of one or more support fasteners 44 configured to connect the support brackets 31 to the integrated electrical assembly 10. The support brackets 31 and connections between the support brackets 31, integrated electrical assembly 10 and wall supports 24 are configured so that the loading and stress of the integrated electrical assembly 10 may be shared between the wall 22 and the wall supports 24. In this manner, the integrated electrical assembly 10 may be preinstalled on a wall 22, and then the wall 22 may be transported to the building structure site and installed in the building structure with the potentially 300-700 lbs. integrated electrical assembly 10 being secured to the wall during transport and installation.

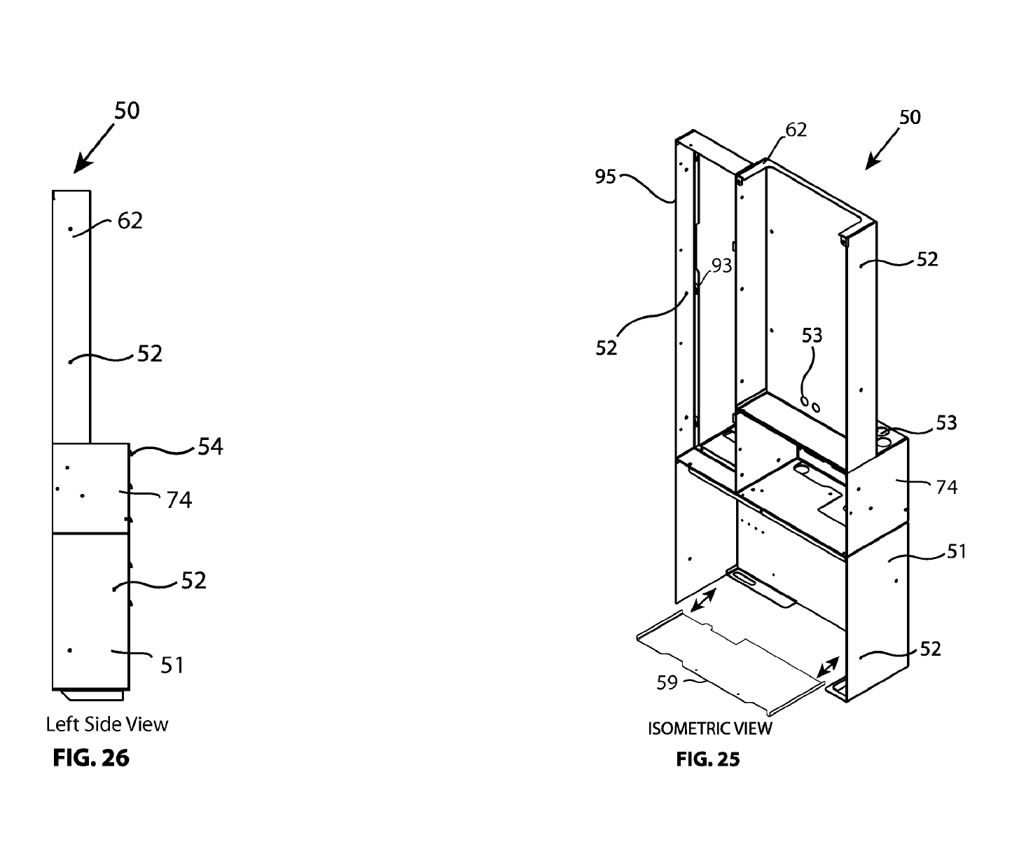

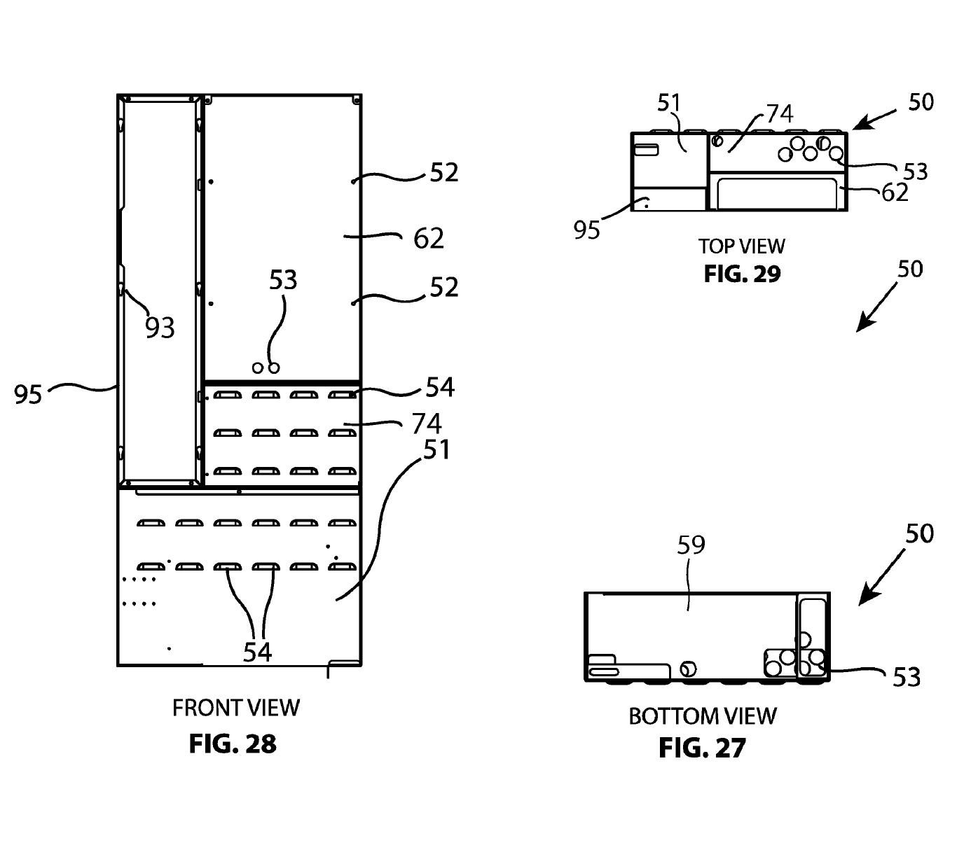

Referring now to FIGS. 25-29, the exemplary master tub 50 that may be used in the integrated electrical assembly 10 is shown in greater detail. The master tub 50 may contain one or more enclosures 51, 62, 74 that are configured and positioned to each contain at least one component that may be used in the integrated electrical assembly 10. The master tub 50 may also include a load center housing collar 95 that is configured to secure a load center to the master tub 50, as discussed further below. The enclosures 51, 62, 74 and load center housing collar 95 of the master tub 50 may be secured to each other by suitable means, such as by welding, bolting or riveting the enclosures 51, 62, 74 and load center housing collar 95 together in order to form the master tub 50. The one or more enclosures of the master tub 50 may include a main electrical feed enclosure 51, a low voltage enclosure 62 and/or a data-com enclosure 74. Each of the enclosures 51, 62, 74 and the load center housing collar 95 may include one or more securing holes 52 that may be used to secure the master tub 50 to the integrated electrical assembly 10 at one or more locations by suitable fastening devices (not shown), such as screws, bolts, pins or rivets. Each enclosure 51, 62, 74 may also include one or more opening/knock-out 53 in order to allow wiring and other connections to be made to the components contained within the master tub 50. The enclosures 51, 62, 74 may also include ventilation ports 54 in order to provide air cooling and/or circulation for the components that may be installed in each enclosure 51, 62, 74. The master tub 50 provides for separate enclosures 51, 62, 74 and the load center housing collar 95 for the various components that may be included in the integrated electrical assembly 10 in order to allow for separate National Recognized Testing Laboratory (NRTL) or foreign equivalent listings for each enclosure. The integrated electrical assembly 10 may be configured so as to provide an inherently protected type NRTL listing that requires zero clearance to combustible materials for installation in wood stud wall and clothing closets with closes in direct contact with such enclosures 51, 62, 74. The master tub 50 may also include a removable access panel 59 that is removable from the main electrical feed enclosure 51. The removable access panel 59 is configured to provide access to the power distribution blocks 43 of the master feed enclosure 40 in order to allow for installation of electrical feeds to the power distribution blocks 43 in the master integrated electrical assembly 10. The removable access panel 59 also provides for access to the power distribution blocks 43 so as to allow for maintenance, such as tightening of connections made by the power distribution blocks 43.

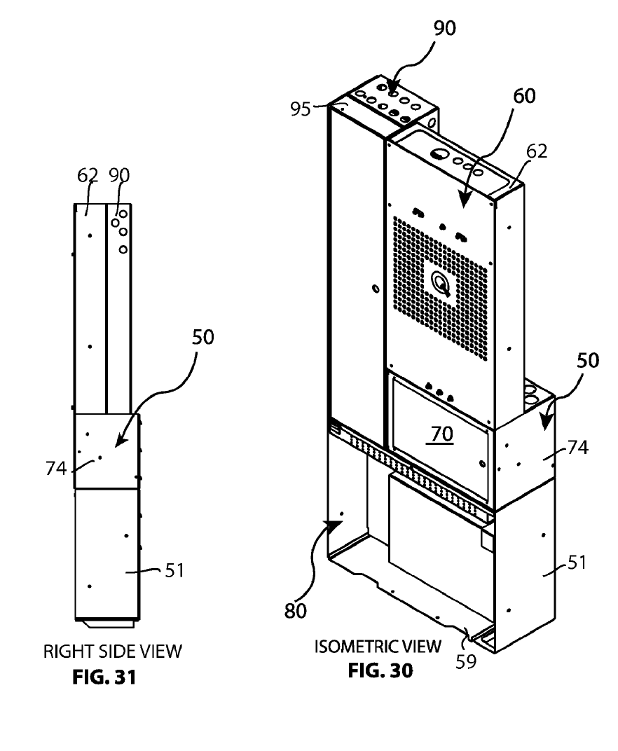

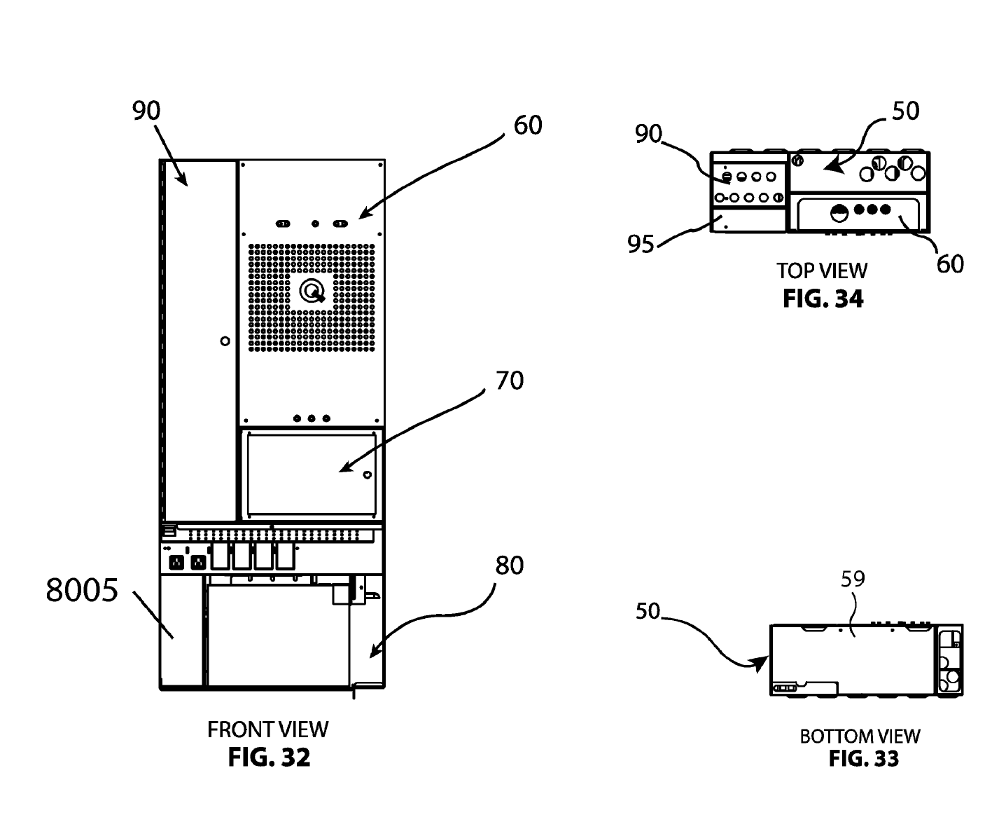

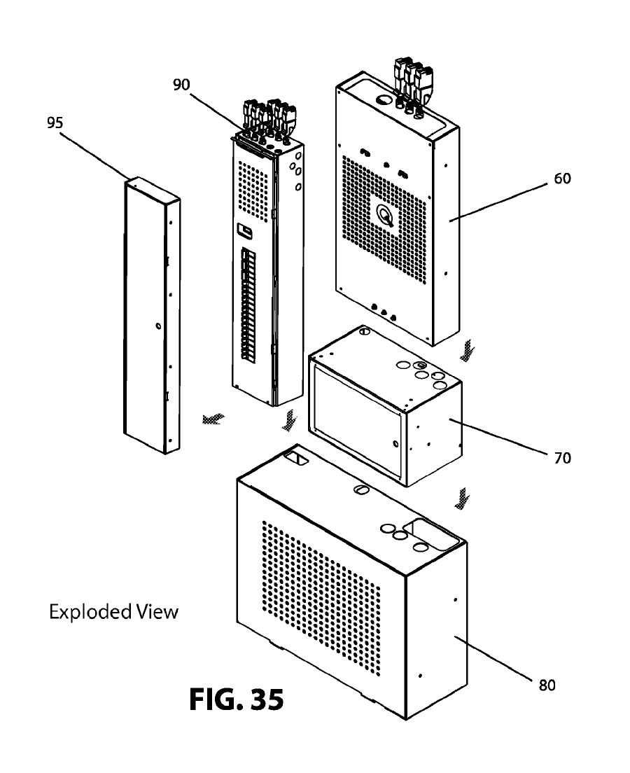

Referring now to FIGS. 30-35, exemplary components that may be installed in the master tub 50 are shown. For example, the exemplary components may include a low voltage power supply unit 60, a data-com component 70, a main electrical feed unit 80 and/or a load center 90. Each one of these components may be configured to obtain a separate NEMA 1 or equivalent NRLT listing for dry environments. It is understood that the present invention is not limited to any particular type of component or number of components that may be included in the master tub 50 and/or the integrated electrical assembly 10. It is contemplated that a variety of types of components, configuration of components and number of components may be used in various aspects of the present invention, and it is understood that the components and component configurations herein discussed and shown are merely exemplary.

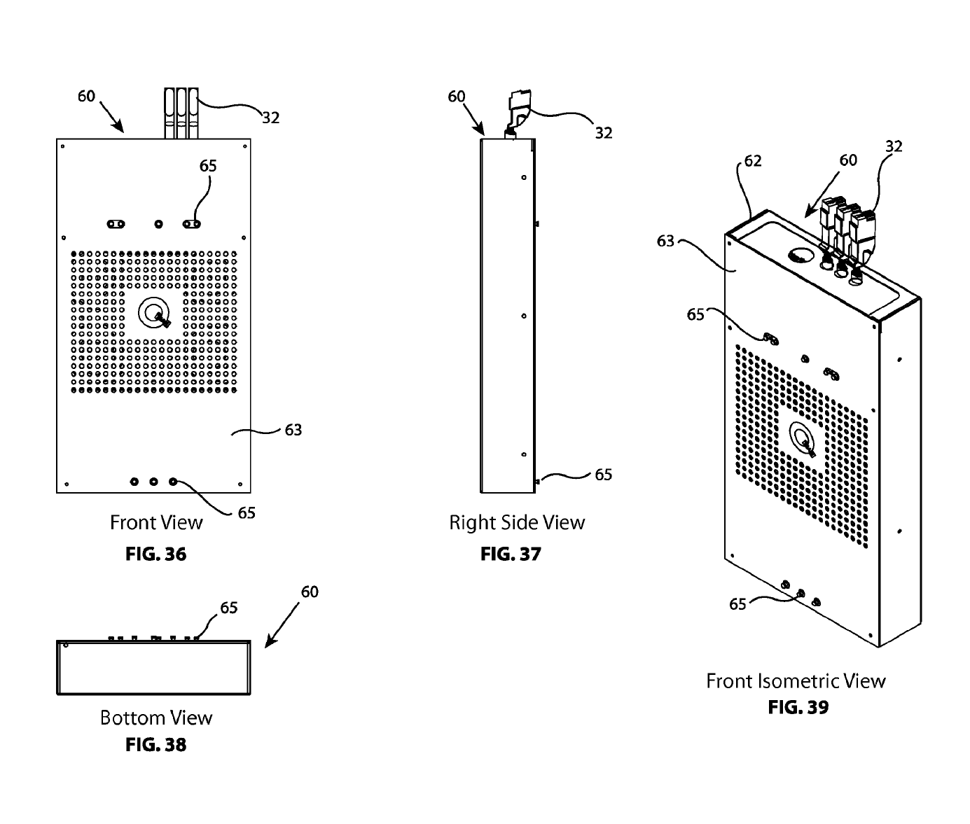

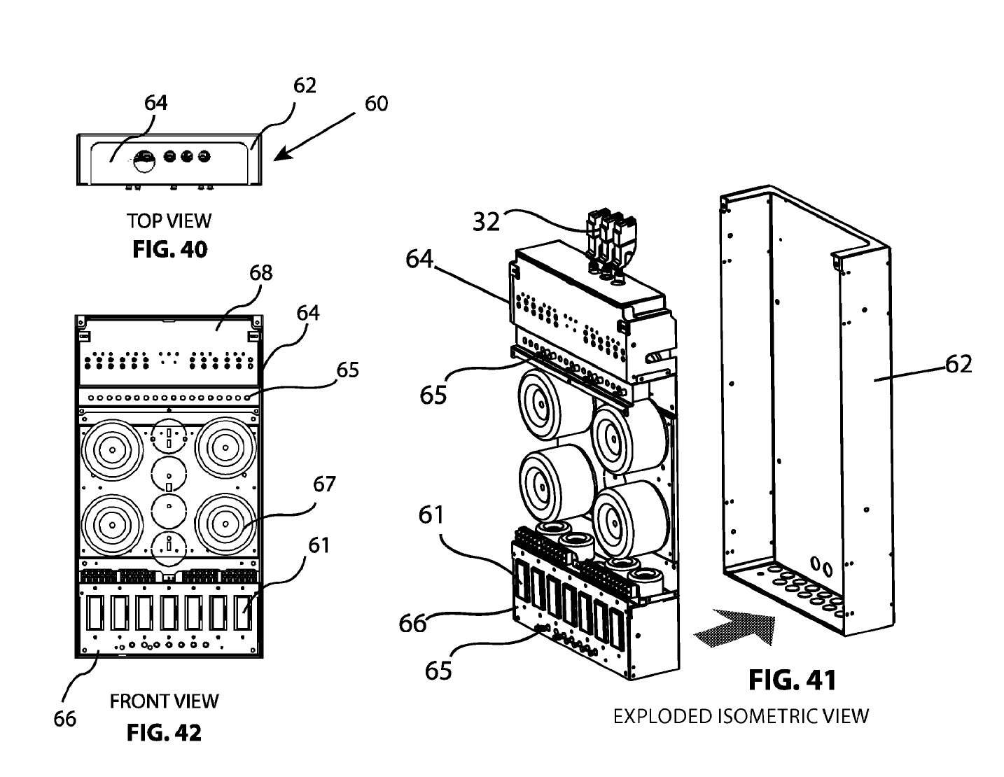

Referring now to FIGS. 36-43 and 43A, an exemplary low voltage power supply unit 60 that may be installed in the integrated electrical assembly 10 according to the present invention or used as a standalone unit is shown. The low voltage power supply unit 60 may be installed in the low voltage enclosure 62 of the master tub 50 or include a separate low voltage enclosure 62. It is understood that by providing the low voltage power supply unit 60 with the capability of being installed in the low voltage enclosure 62 of the master tub 50, a power tray 64 of the low voltage power supply unit 60 can be pre-wired and pre-fabricated, and then merely attached to the low voltage enclosure 62 of the master tub 50 of the integrated electrical assembly 10. In addition, in the event that the low voltage power supply unit 60 needs to be replaced for upgrade and/or repair the power tray 64 of the low voltage power supply unit 60 can be easily removed and replaced. The low voltage power supply unit 60 may also be provided with a low voltage cover 63 for installation over the power tray 64 position within the low voltage enclosure 62.

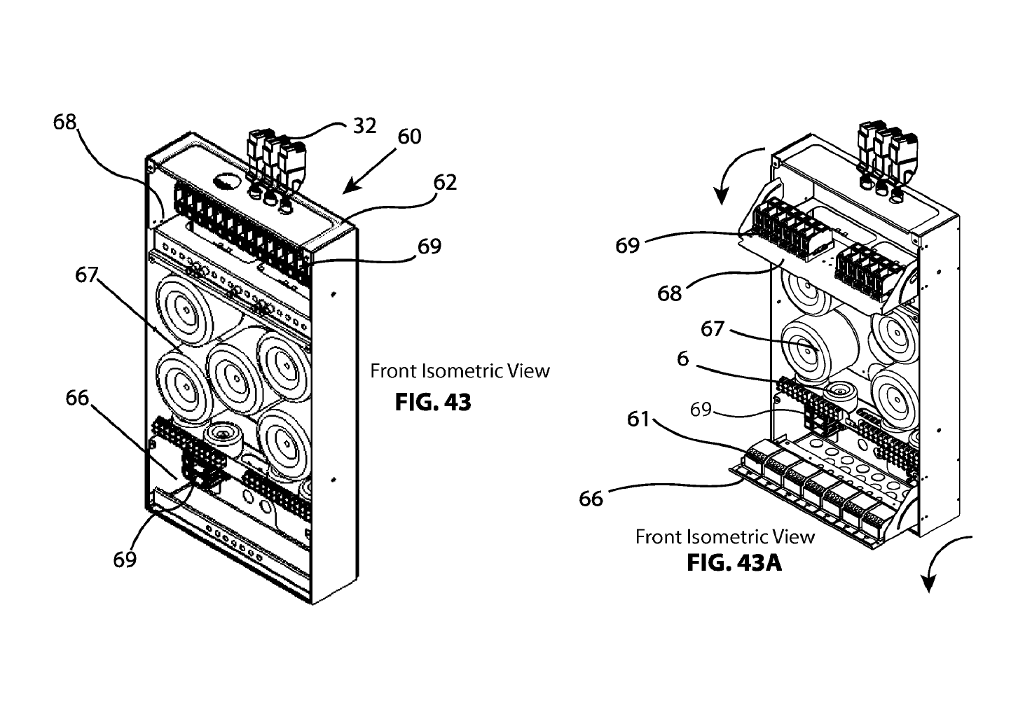

Still referring to FIGS. 36-43 and 43A, the power tray 64 is configured to contain one or more components of the low voltage power supply unit 60. For example, the power tray 64 may include a line voltage control compartment 66 with a fold-out door for accessibility to the line voltage control compartment 66, and a low voltage connection compartment 68 that may also include a fold-out door for accessibility to the low voltage connection compartment 68. However, it is understood that the line voltage control compartment 66 and the low voltage connection compartment 68 may also not be provided with a fold-out door, as shown for example in FIG. 43, and in this configuration the components within the compartments may be secured directly to the compartments. It is also understood that separating the line voltage from the low voltage components provides for additional electronic shock safety. The low voltage connection compartment 68 may be configured for making appropriate low voltage connections between the low voltage power supply unit 60 and low voltage devices of the building structure and/or individual units of the building structure. The line voltage control compartment 66 may include one or more control devices 61, for example dimmers, timers and/or switches that may be manually, wired or wirelessly controlled, for example by RF control. The line voltage control compartment 66 may also include one or more multi-wire connectors 69. The low voltage connection compartment 68 may also include one or more multi-wire connectors 69 that are configured to connect wiring from the one or more cable connectors 32 that may be installed on the low voltage power supply unit 60.

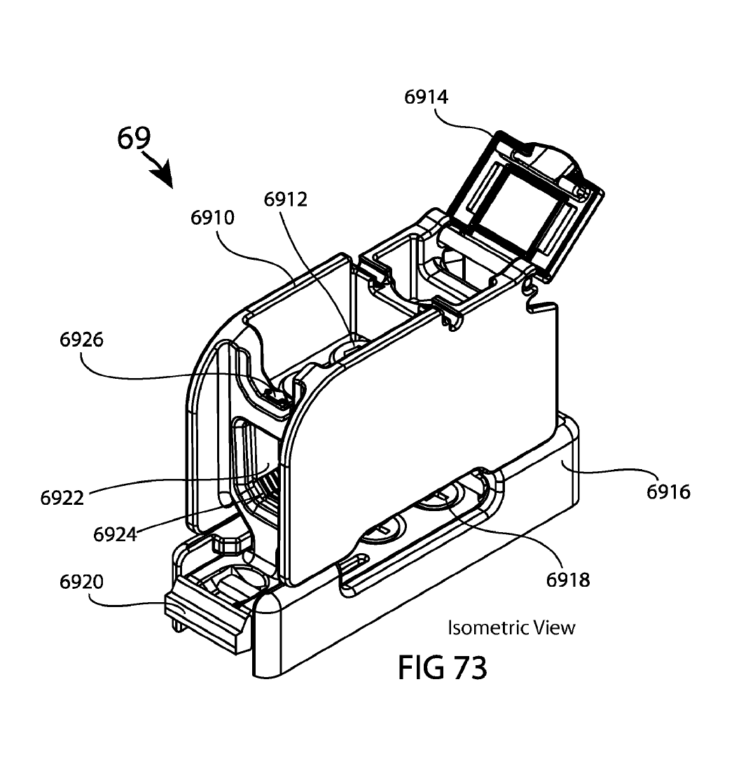

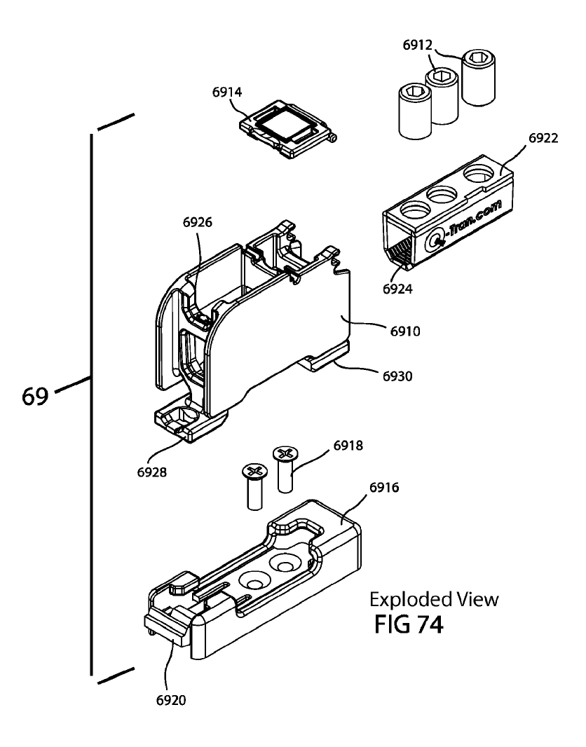

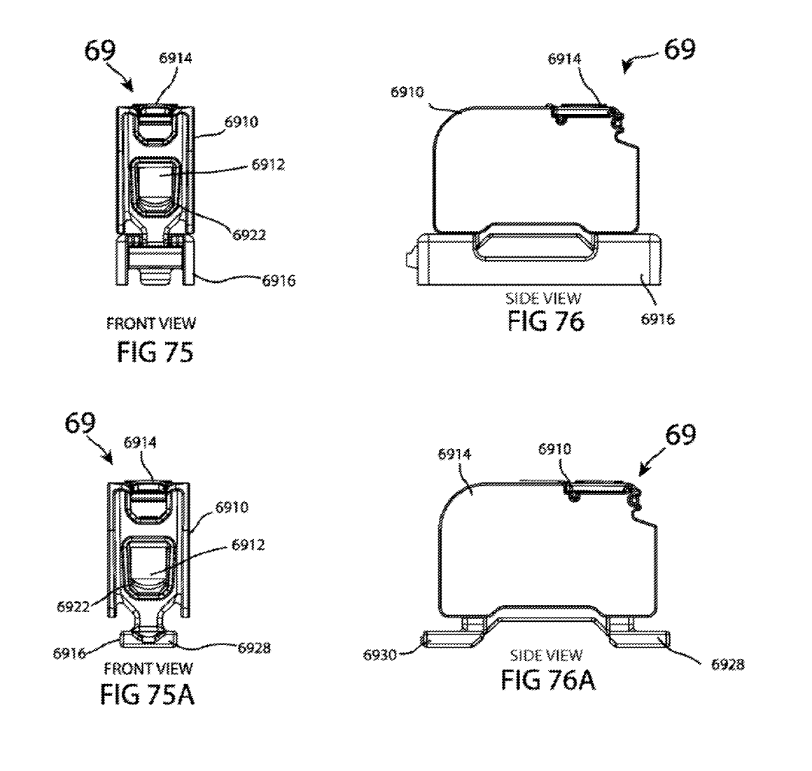

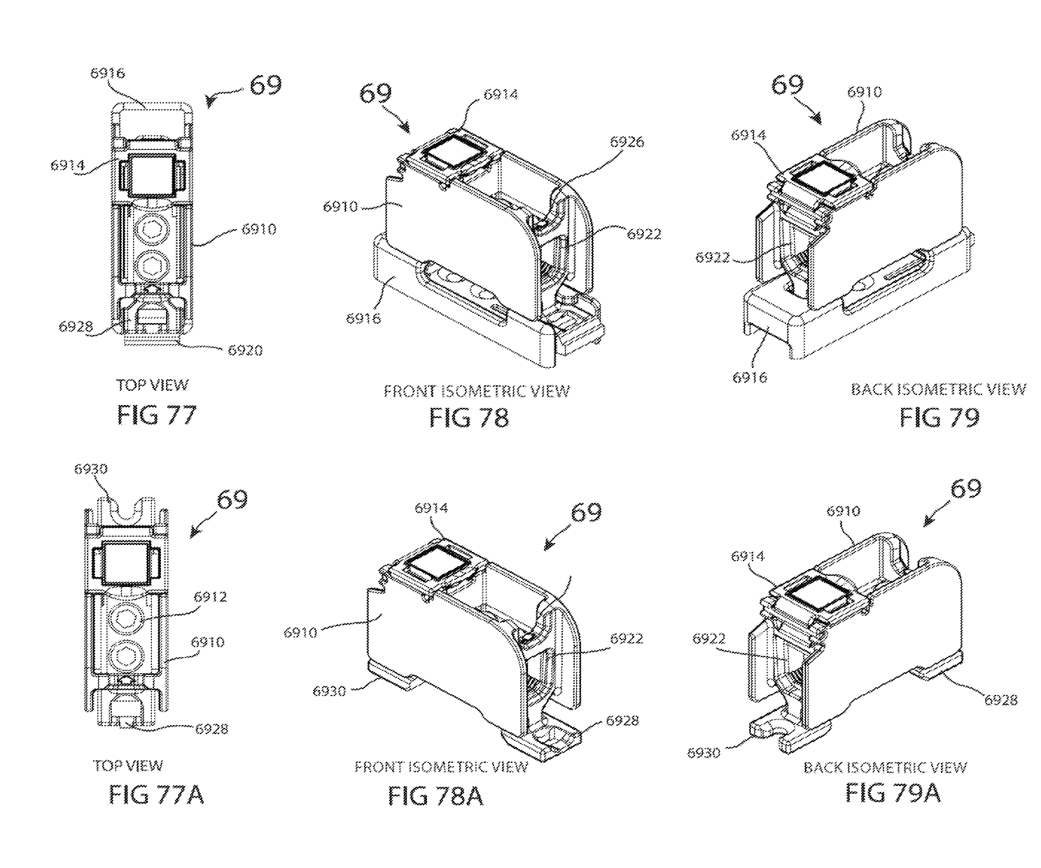

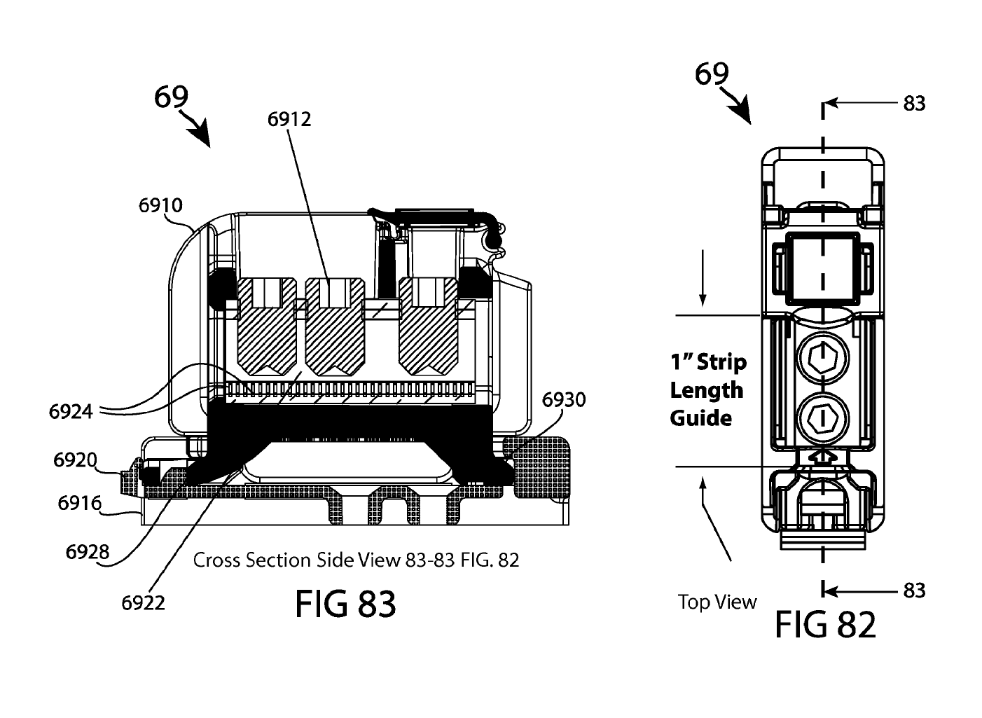

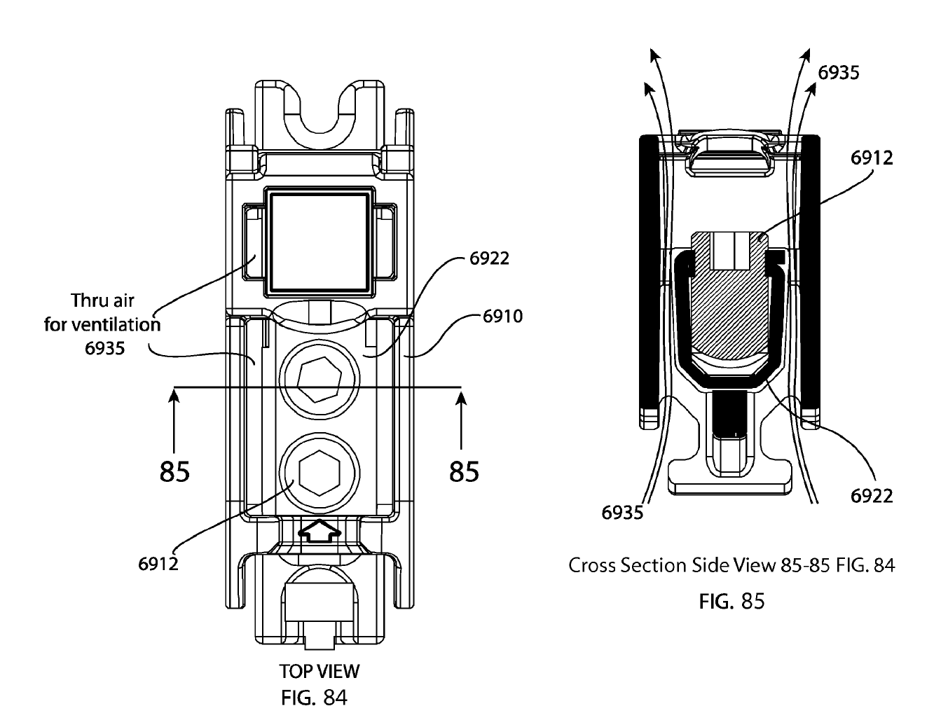

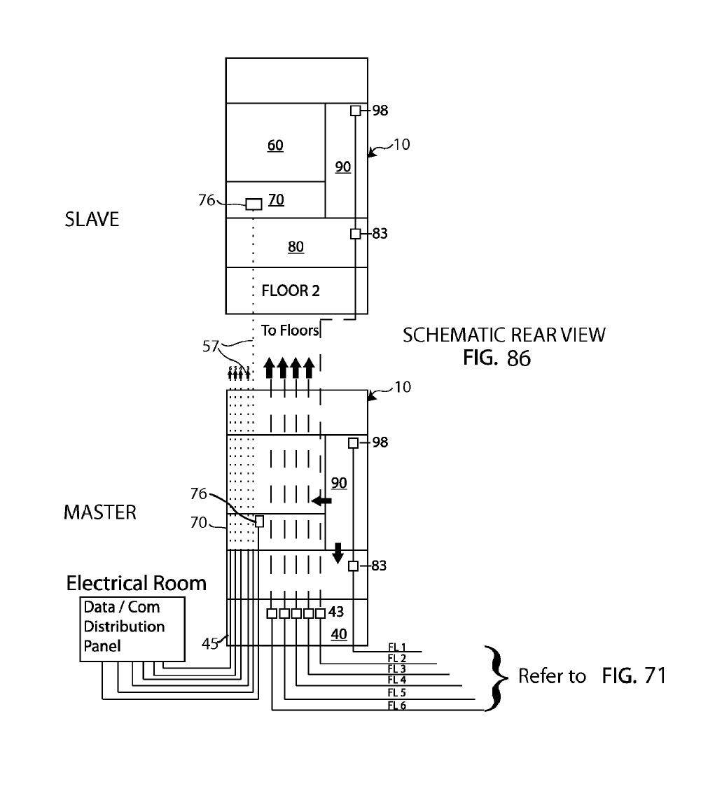

An exemplary multi-wire connector 69 that may be used with the low voltage power supply unit 60 is shown in detail in FIGS. 73-85 and 75A-81A. The multi-wire connector 69 may include a terminal block 6922 that contains at least two set screws 6912 that can be loosened and tightened relative to the terminal block 6922. The terminal block 6922 may be made from tin or nickle plated copper or copper alloy, and the set screws 6912 may be made from a stainless steel. The terminal block 6922 may preferably have one or more grooves 6924 formed in a bottom surface of the terminal block 6922. The grooves 6924 are configured and positioned within the terminal block 6922 so as to provide an improved frictional surface for the capture of wires installed in the terminal block. The multi-wire connector 69 may also include a housing 6910 that is dimensioned to receive and contain the terminal block 6922, but allow for ventilation space 6935 between the housing 6910 and the terminal block 6922. The ventilation space 6935 is configured for dissipation of heat that may be generated by the terminal block 6922 while in use, and reduces the amount of heat that may be retained by the housing 6910 of the multi-wire connector. Since ampacity is determined by temperature rise, the ventilation space 6935 provides for higher ampacity ratings for multi-wire connector 69, lower operating temperatures and an increased level of safety. The housing 6910 may be made from a polycarbonate resin thermoplastic, and may preferably be transparent and/or clear, which facilitates installation and inspection by allowing increased visualization of the components of the multi-wire connector 69. The housing 6910 may include a strip length guide 6926 in order to facilitate proper installation of wiring into the multi-wire connector 69. The housing 6910 of the multi-wire connector 69 may also include a set screw cover 6914 positioned over at least one of the set screws 6912 and configured for movement between an open (e.g FIG. 73) and a closed position (e.g. FIG. 78). The set screw cover 6914 may also contain an indication (not shown) that provides information regarding the multi-wire connector 69. The set screw cover 6914 also provides an openable cover to prevent an installer from adjusting and/or loosening of a set screw 6912 that may connect to wiring that has been pre-wired prior to installation of the multi-wire connector 69, a color coded plug in (not shown) may also be inserted into the set screw 6912 to provide additional visual indications. The housing 6910 of the multi-wire connector 69 may also include mounting tabs 6928, 6930 that are configured to secure the housing 6910 to a base mount 6916 that may also be included in the multi-wire connector 69. The base mount 6916 may include a housing lock and release tab 6920, the operation and function of which will be discussed further below. The base mount 6916 may be made from polycarbonate resin thermoplastic.

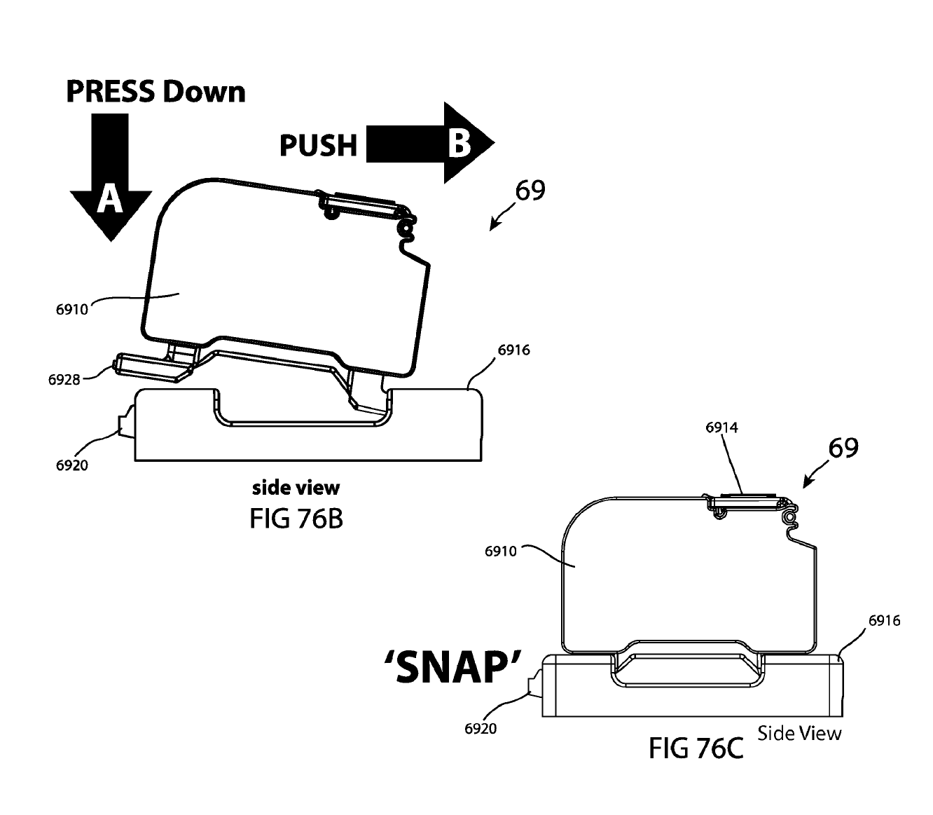

Referring particularly to FIGS. 73-83, which show the housing 6910 of the multi-wire connector 69 attached to the base mount 6916, one of the mounting tabs 6930 may slide into the base mount 6916, and then the housing 6910 pressed towards the base mount 6916 in order to cause the other mounting tab 6928 to be secured by the housing lock and release tab 6920. The housing lock and release tab 6920 may be configured to snap onto the mounting tab 6928 in order to removably secure the housing 6910 to the base mount 6916, as shown for example in FIGS. 76B and 76C. Base mount 6916 allows for inspection during installation, facilitates maintenance and shortens installation time. Furthermore, one or more base mounts 6916 may be molded together in order to provide a bank of base mounts 6916 for one or more housings 6910 to be secured to.

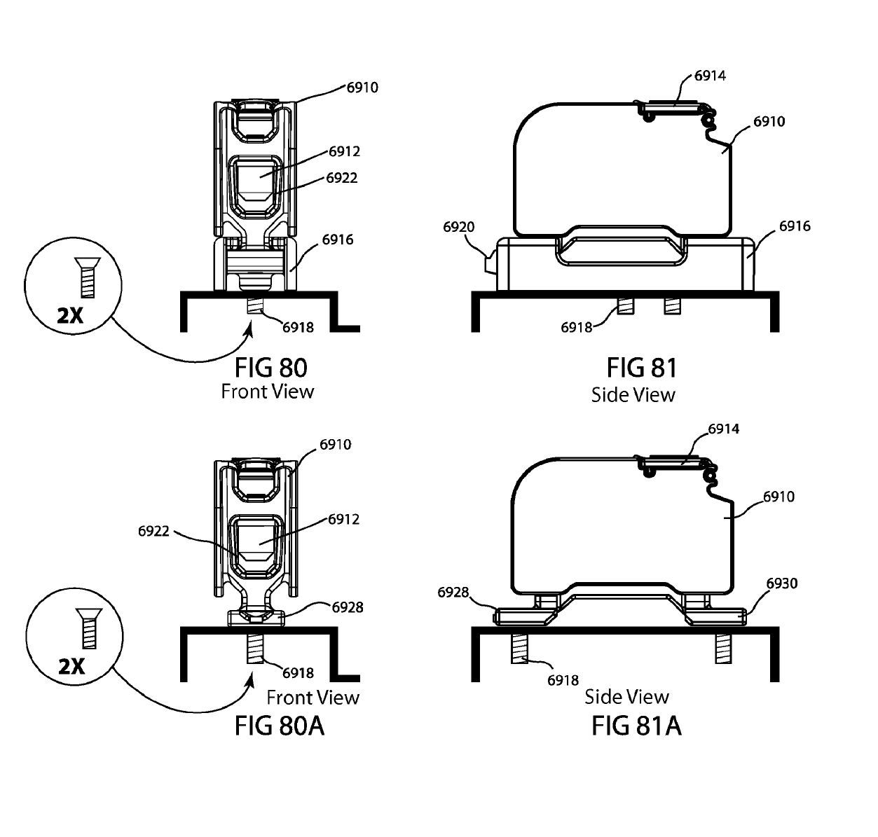

Referring now to FIGS. 80-81, the multi-wire connector 69 may be secured to a surface by one or more mounting fasteners 6918 secured to the base mount 6916 and the surface. In this configuration, the multi-wire connector 69 may be removed from the base mount 6916 in order to facilitate wiring connections made with the multi-wire connector 69. In the alternative, as shown in FIGS. 80A-81A, the multi-wire connector 69 may be secured directly to a surface by one or more mounting fasteners 6918 through the mounting tabs 6928, 6930. The mounting fasteners 6918 may be any known fasteners, such as screws or bolts.

The multi-wire connector 69 is configured to secure at least one wire to the terminal block 6922 by one of the set screws 6912, and then at least one other wire to the terminal block 6922 by the other set screws 6912. Preferably, two set screws 6912 may be used to secure more than one wire to the terminal block 6922. For example, the multi-wire connector 69 may be configured to accommodate any combination of wire types and sizes, and preferably may be configured to be Underwriters Laboratories (UL) listed as a recognized component that can accommodate any wire size from No. 18 AWG to No. 1/0, and even more preferably may be configured to accommodate at least 1-2 No. 4 AWG, 1-4 No. 6 AWG, 1-6 No. 8 AWG, 1-10 No. 10 AWG, 1-16 No. 12 AWG, 1-25 No. 14 AWG, 1-40 No. 16 AWG and/or 1-65 No. 18 AWG. The multi-wire connector 69 may also be configured for voltages up to and including 600V, and amperage up to and including 150 amps. The multi-wire connector 69 may also be configured to obtain UG ratings of B, C and/or D. A multi-wire connector terminal block greatly improves the quality of installation, shortens installation time and thereby lowers labor related costs.

Referring now to FIG. 72, in which an exemplary use of the multi-wire connector 69 for the integrated electrical assembly 10 is shown. The multi-wire connector 69 may be used to connect one or more wires coming from the load center 90 to the low voltage power supply unit 60. In this manner, the connections from the components of the low voltage supply unit 60 have already been made to the multi-wire connector 69 so that all that is required to connect the load center 90 wiring to the low voltage power supply unit 60 is connections between the wiring and the multi-wire connector 69.

Referring again to FIGS. 36-43 and 43A, the power tray 64 may also be configured to contain one or more transformers, for example torrodial transformers, current transformers, bridge rectifiers, capacitors, inductors, such as chokes, electronic drivers, for example electronic LED drivers and dimmers. The power tray 64 of the low voltage power supply unit 60 may be configured for AC or DC output depending upon the load requirements to the individual unit of the building structure. For example, the low voltage power supply unit 60 may be configured to supply the lighting systems of the individual unit and/or building structure. Some advantages of low voltage lighting include that it is safer than line voltage lighting, allows for smaller fixtures, reduces noise, has minimal EMF and allows for live conductors to be used, such as cable or rail conductor systems. It is generally understood that low voltage refers to voltage levels of 30V or less, which many believe to be healthier than higher voltages. The power tray 64 may also include one or more 120/120V isolated power supplies for hospital related purposes. As shown for example in FIGS. 41-43 and 43A the power tray 64 of the low voltage power supply unit 60 may include at least one transformer 67 and may include at least one inductor 6. The low voltage power supply unit 60 may also include one or more circuit breakers 65, which may be provided to protect line voltage and/or low voltage circuits.

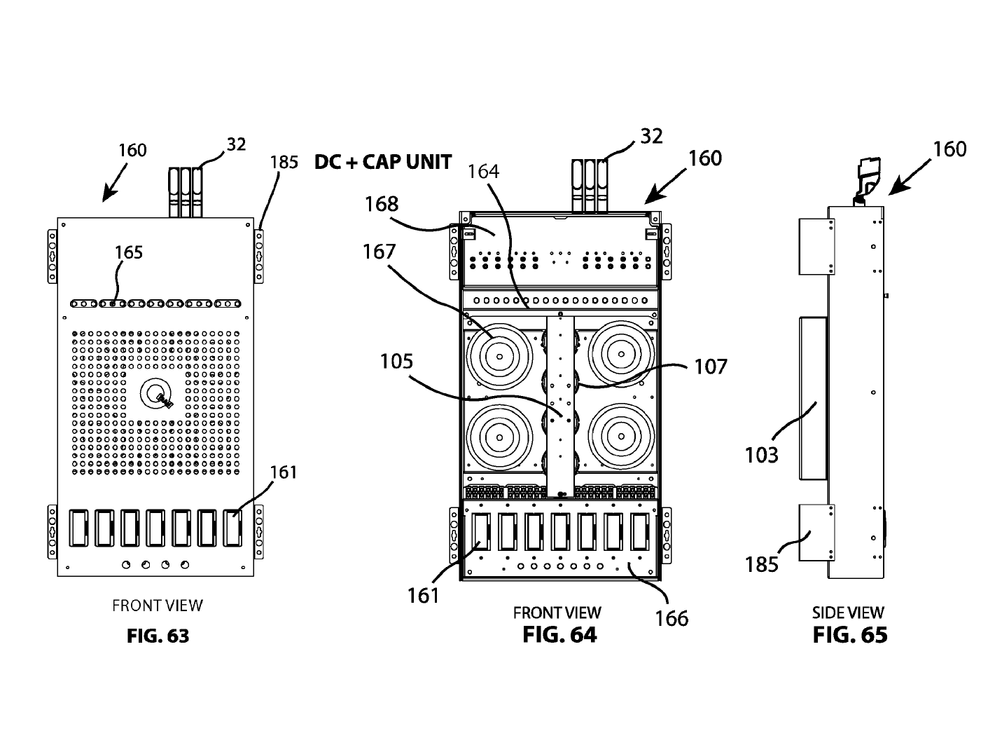

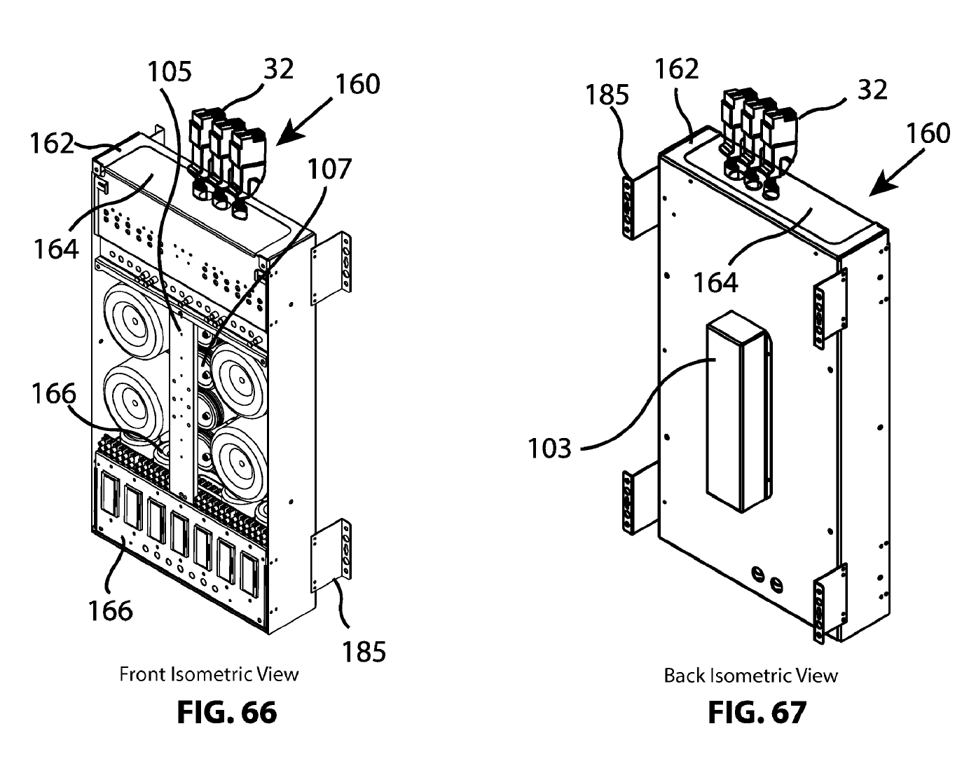

Referring now to FIGS. 63-67, another exemplary low voltage power supply unit 160 that may be installed in the integrated electrical assembly 10 according to the present invention or used as a standalone unit is shown. The low voltage power supply unit 160 may be installed in the low voltage enclosure 62 of the master tub 50 or include a separate low voltage enclosure 162. The low voltage power supply unit 160 may also be provided with a low voltage cover 163 for installation over the low voltage enclosure 62, 162. In order to provide the low voltage power supply unit 160 as a standalone unit, one or more surface wall mounting brackets 185 may be affixed to the low voltage enclosure 162 in order to provide a mechanism for securing the low voltage power supply unit 160 to a wall surface. The power tray 164 may include a line voltage control compartment 166 with a fold-out door for accessibility to the line voltage control compartment 166, and a low voltage connection compartment 168 that may also include a fold-out door for accessibility to the low voltage connection compartment 168. The low voltage connection compartment 168 may be configured for making appropriate low voltage connections between the low voltage power supply unit 160 and low voltage devices of the building structure and/or individual units of the building structure. The line voltage control compartment 166 may include one or more control devices 161, for example dimmers, timers and/or switches that may be manually, wired or wirelessly controlled, such as RF controlled. The line voltage control compartment 166 may also include one or more multi-wire connectors (not shown). The low voltage connection compartment 168 may also include one or more multi-wire connectors (not shown) that are configured to connect wiring from the one or more connectors (not shown) that may be installed on the low voltage power supply unit 160. In this exemplary embodiment of the low voltage power supply unit 160, the power tray 164 may include at least one transformer 167, at least one inductor 106, at least one capacitor 107 and at least one bridge rectifier 105 or combinations thereof. However, it is understood that the present invention is not limited to any particular combinations or types of components installed in the power tray 164 of the low voltage power supply unit 160. Instead, it is understood that any combination of transformers, inductors, capacitors, rectifiers and/or dimmers may be included in the low voltage power supply unit 160. In the event that one or more capacitors 107 are included in the low voltage power supply unit 160, the low voltage enclosure 162 may include an extension cover 103 for covering the part of the capacitors 107 that may extend out of the low voltage enclosure 162. The low voltage power supply unit 160 may also include one or more circuit breakers 165, which may be provided to protect line voltage and/or low voltage circuits.

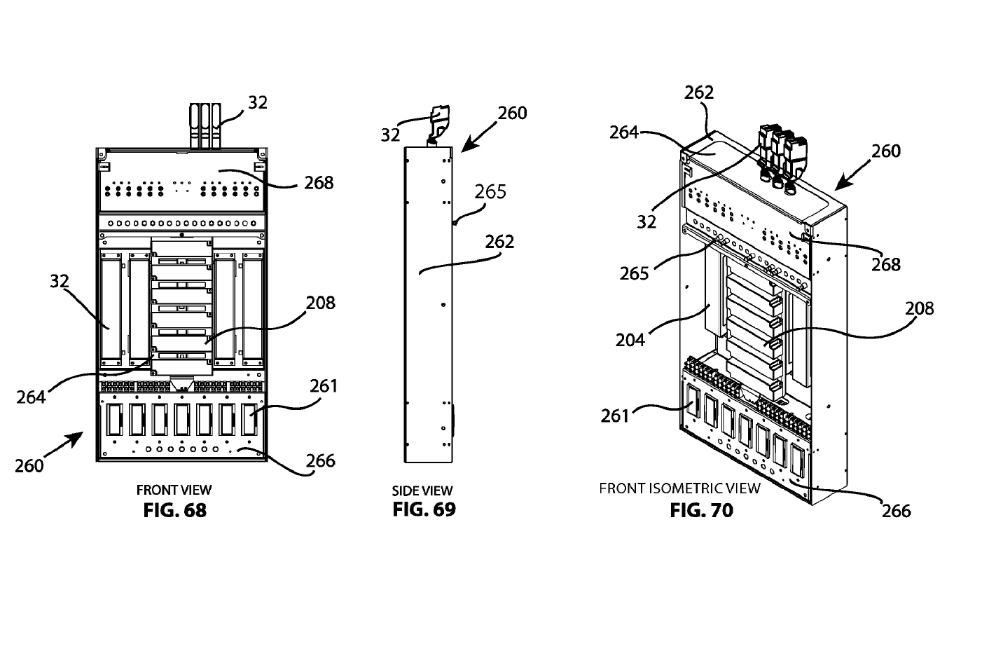

Referring now to FIGS. 68-70, another exemplary low voltage power supply unit 260 that may be installed in the integrated electrical assembly 10 according to the present invention or used as a standalone unit is shown. The low voltage power supply unit 260 may be installed in the low voltage enclosure 62 of the master tub 50 or include a separate low voltage enclosure 262. The low voltage power supply unit 260 may also be provided with a low voltage cover (not shown) for installation over the low voltage enclosure 62, 262. The low voltage power supply unit 260 may include a power tray 264. The power tray 264 may include a line voltage connection compartment 266 with a fold-out door for accessibility to the line voltage connection compartment 266, and a low voltage connection compartment 268 that may also include a fold-out door for accessibility to the low voltage connection compartment 268. The low voltage connection compartment 268 may be configured for making appropriate low voltage connections between the low voltage power supply unit 260 and low voltage devices of the building structure and/or individual units of the building structure. The line voltage connection compartment 266 may include one or more control devices 261, for example dimmers, timers and/or switches that may be manually, wired or wirelessly controlled, such as RF controlled. The line voltage connection compartment 266 may also include one or more multi-wire connectors (not shown). The low voltage connection compartment 268 may also include one or more multi-wire connectors (not shown) that are configured to connect wiring from the one or more connectors (not shown) that may be installed on the low voltage power supply unit 260. In this exemplary embodiment of the low voltage power supply unit 260, the power tray 264 may include at least one electronic LED driver 204 and may include at least one driver dimmer 208. However, it is understood that the present invention is not limited to any particular combinations or types of components installed in the power tray 264 of the low voltage power supply unit 260. Instead, it is understood that any combination of transformers, inductors, capacitors, rectifiers and/or dimmers may be included in the low voltage power supply unit 260. The low voltage power supply unit 260 may also include one or more circuit breakers 265, which may be provided to protect line voltage and/or low voltage circuits.

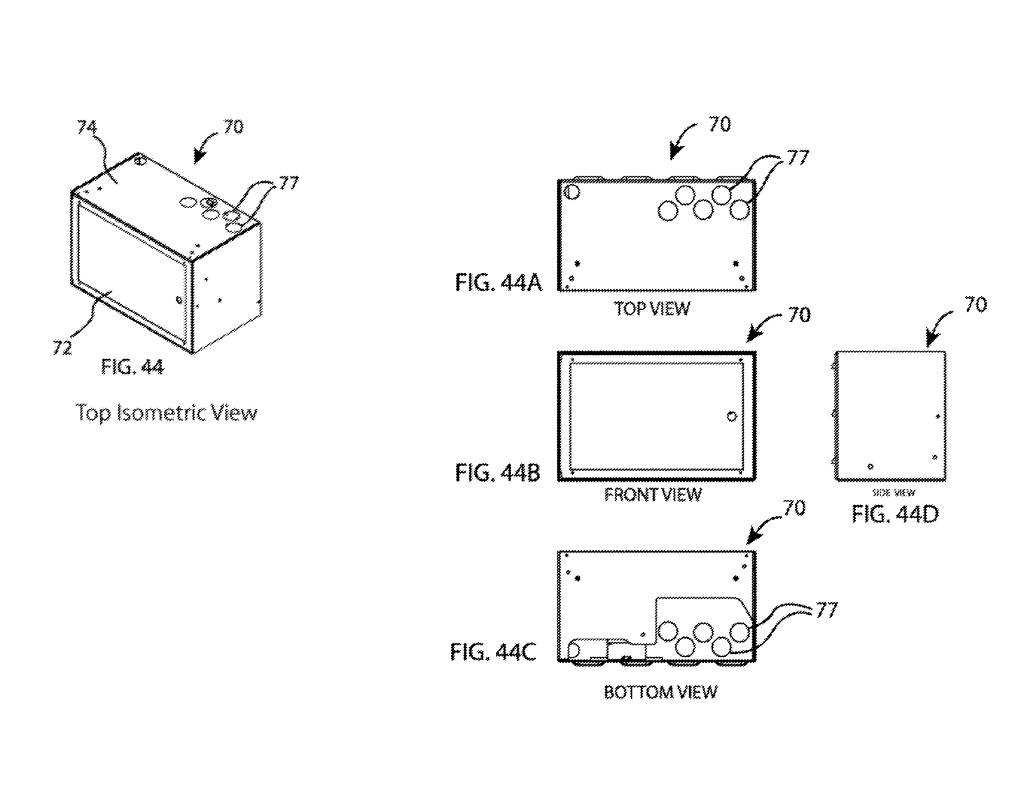

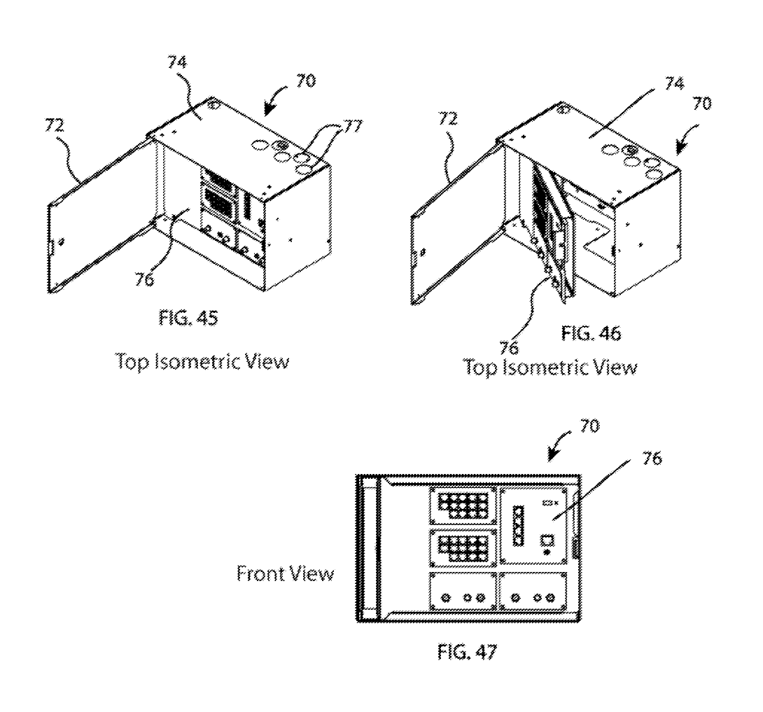

Referring now to FIGS. 44, 44A-44D and 45-47, an exemplary data-com component 70 that may be installed in the integrated electrical assembly 10 according to the present invention is shown. The data-come component 70 may be installed in the data-com enclosure 74 of the master tub 50. The data-com component 70 may include an access door 72, which may be formed from solid steel, have a steel frame with a plastic door or be formed from a clear plastic or similar material, and a data-com panel 76 configured for allowing appropriate connections to be made to the data-com component 70. The data-com panel 76 is configured for removal from the data-com component 70 in order to allow installation and/or repair of the wiring connected to the data-com panel 76. In addition, since the data-com panel 76 may be removal, the data-com panel 76 can be upgraded to accommodate newer technologies. The data-com component 70 may also include one or more openings/knock-outs 77 in order to allow wiring and/or other parts of the data-com component 70 to be connected to other locations outside of the data-com component 70. The data-com component 70 within the data-com enclosure 74 may be a Class 2 enclosure, and the data cables provided to the enclosure may be run inside flexible plastic conduit. This allows for efficient re-wiring of the data-com component 70 in the event of repair and/or upgrade to the wiring of the data-com component 70. Exemplary wires and components that may be run into and included in the data-com component include television wires, such as coaxial cables, fiber optics, CAT 5 or higher communication wires, routers, and other entertainment, WI-FI and telephone wires and components. For example, as shown in FIG. 86, the data-com component 70 of the integrated electrical assembly 10 may be configured to receive one or more data-com wires and/or conduits from a data-com distribution panel of the building structure. The data-com wire for the individual unit of the integrated electrical assembly 10 may then be connected to the data-com panel 76 of the data-com component 70 in order to provide the appropriate data-com services to the ports of the data-com panel 76. Additional data-com wires and/or conduits are passed through the data-com component 70 of the integrated electrical assembly 10 and into one or more low voltage risers 57 (shown in greater detail in FIGS. 14C, 14D and 14E) that are connected to another integrated electrical assembly 10 on a separate floor of the building structure. The additional data-com wires and/or conduits are then appropriately connected to the data-com panel 76 of the data-com component 70 for that integrated electrical assembly 10. Since the data-com components 70 of the integrated electrical assemblies 10 of the building structure are connected in this manner it allows for efficient re-wiring of the data-com components 70 from the data-com distribution panel in order to allow for upgrades and/or repairs to be made to the data-com system of the building structure.

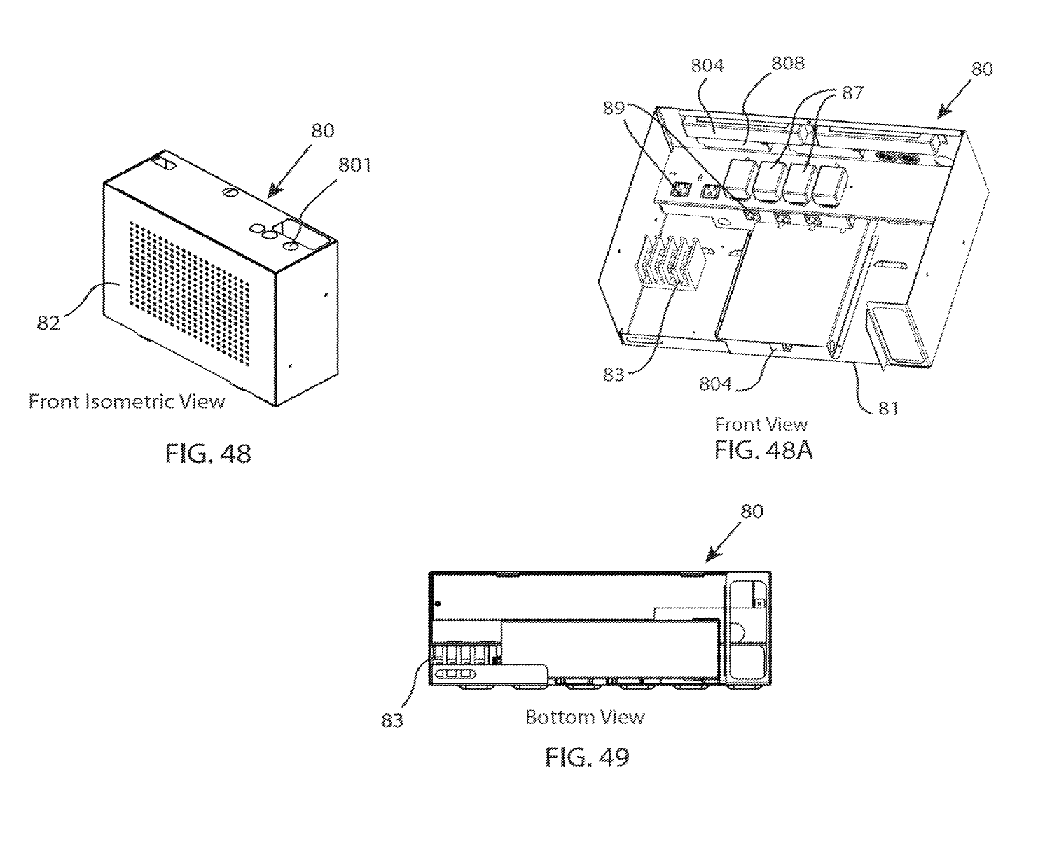

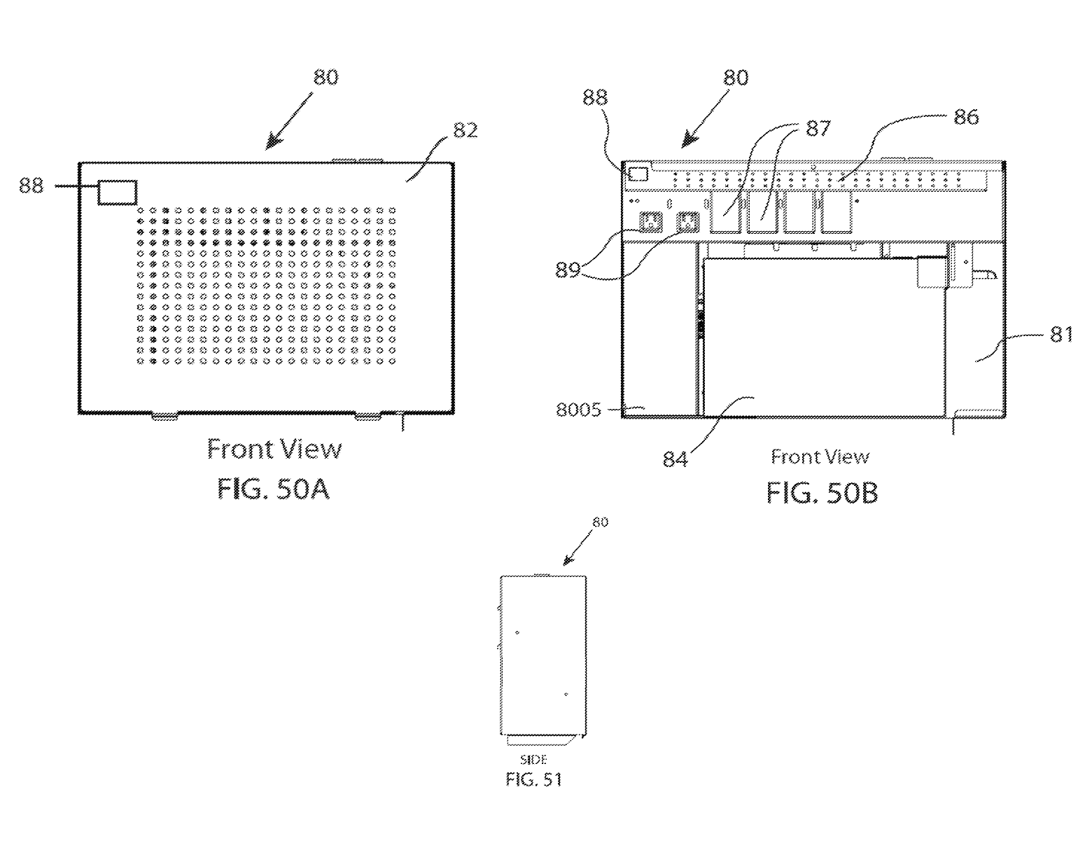

Now referring to FIGS. 48, 48A, 49, 50A, 50B and 51, an exemplary main electrical feed unit 80 that may be installed in the integrated electrical assembly 10 according to the present invention is shown. The main electrical feed unit 80 of the integrated electrical assembly includes an electrical assembly power distribution block 83 that is configured for connection to an electrical feed line from an electrical room, if the integrated electrical assembly 10 is acting as the master electrical distribution node for slave integrated electrical assemblies 10, or to an electrical feed line from the master integrated electrical assembly 10 acting as the electrical distribution node. These arrangements are shown for example in FIG. 71, in which the electrical feed line 7101 for the master integrated electrical assembly 10 is connected to the electrical assembly power distribution block 83, and the other feed lines 7102, 7103, 7104, 7105, 7106 are connected to the power distribution blocks 43 of the master integrated electrical assembly 10, and then connected to each respective slave integrated electrical assembly 10 by the high voltage risers 56 containing wiring connected to the power distribution blocks 43 of the master integrated electrical assembly 10 and the electrical assembly power distribution blocks 83 of the slave integrated electrical assemblies 10. The electrical assembly power distribution block 83 is also configured for connection to one or more lugs 98 of the load center of the integrated electrical assembly 10, as discussed further below.

Referring again to FIGS. 48, 48A, 49, 50A, 50B and 51, the main electrical feed unit 80 may also include a high voltage feed cover 8005 positioned to form a compartment within the main electrical feed unit 80 for the electrical assembly power distribution block 83 and the high voltage lines connected to the electrical assembly power distribution block 83. The main electrical feed unit 80 may also be configured in order to provide back-up and/or emergency power to other components of the integrated electrical assembly 10 in the event of loss of power. For example, the main electrical feed unit 80 may include a power inverter 84 with a battery unit, for example a 120V inverter. The power inverter 84 may be an emergency power pack inverter providing 120V in order to provide power to transformers, LED drivers to power the building structure's exterior lighting systems, individual units' interior lighting systems and/or emergency lighting systems. Thereby, the lighting systems may be used during normal operation and for emergency lighting. The power inverter 84 may be replaced with a transformer to power hospital outlets in order to provide isolated 120V power. The main electrical feed unit 80 may include a low voltage and/or data-com conduit 81 and a removable cover 82, which may be ventilated. The main electrical feed unit 80 may also include one or more openings/knock-outs 801 for running appropriate wiring to and/or from the alternative power unit. The main electrical feed unit 80 may also include an electronic driver and/or dimmer module 86 that includes one or more electronic LED drivers 804 and, if desired, one or more driver dimming modules 808, and a switch 88 coupled to a torrodial transformer and/or the electronic driver and/or dimmer module 86 that activates low voltage lighting strip 17 when the swing door 12 is opened. The main electrical feed unit 80 may also include one or more plug-in transformers 87 to provide low voltage Class 2 power to electronic devices in the data-com component 70 and other compartments as required or to remote external locations within an individual unit. The main electrical feed unit 80 may also include one or more plugs 89 so that additional electronic devices can be plugged directly into the main electrical feed unit 80.

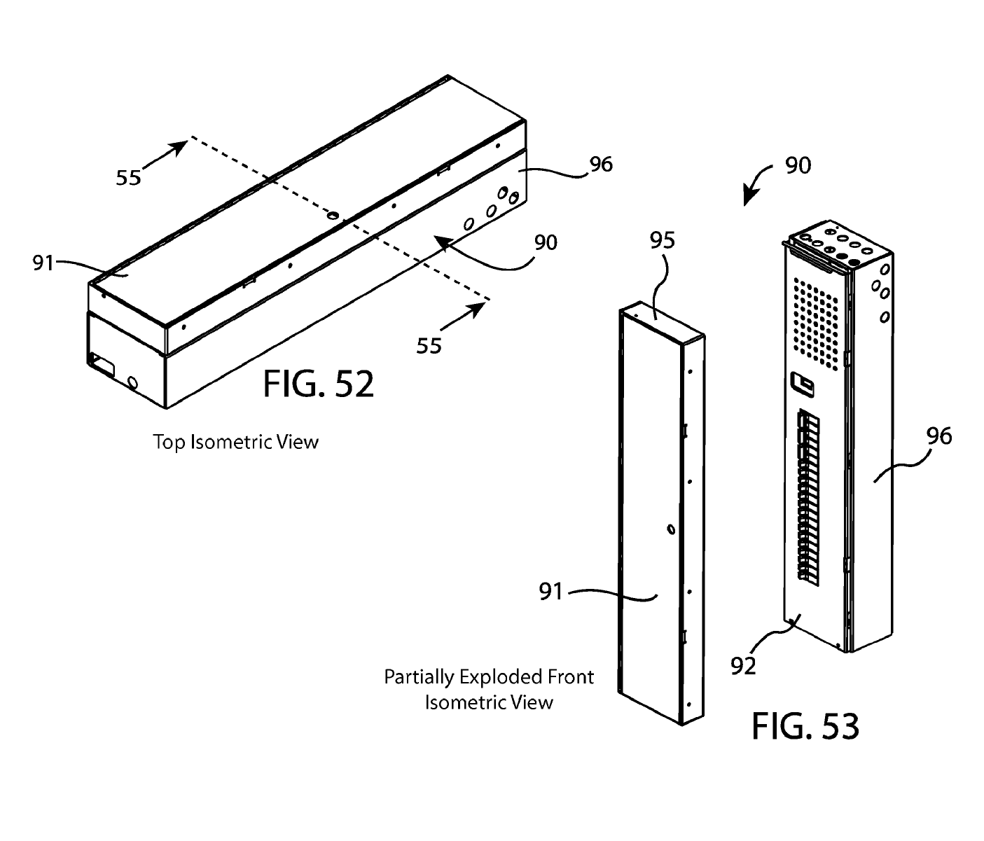

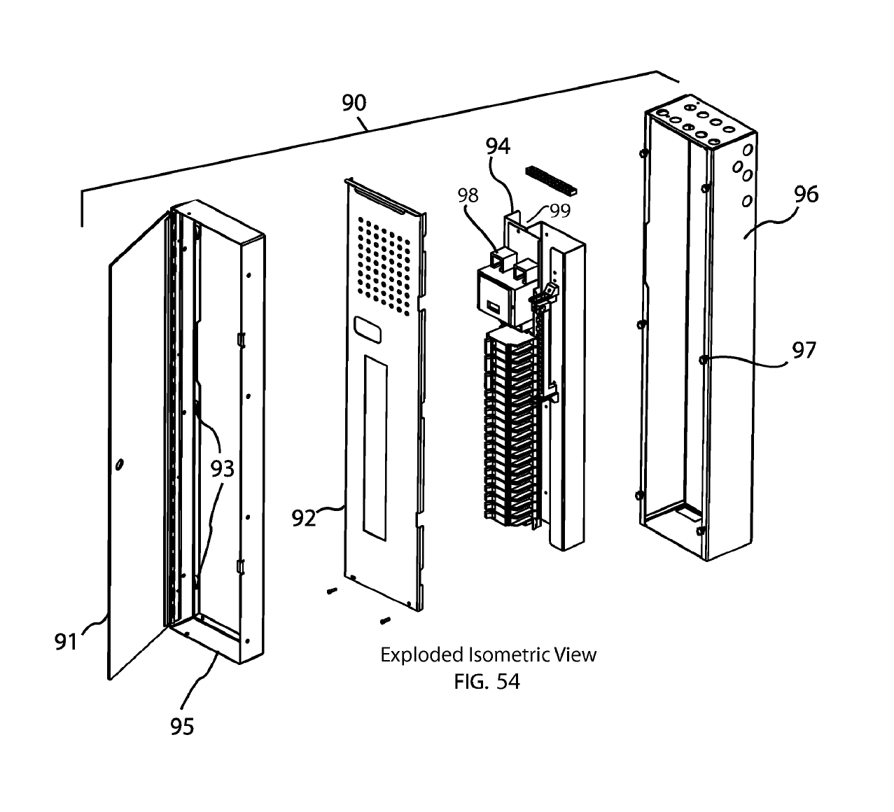

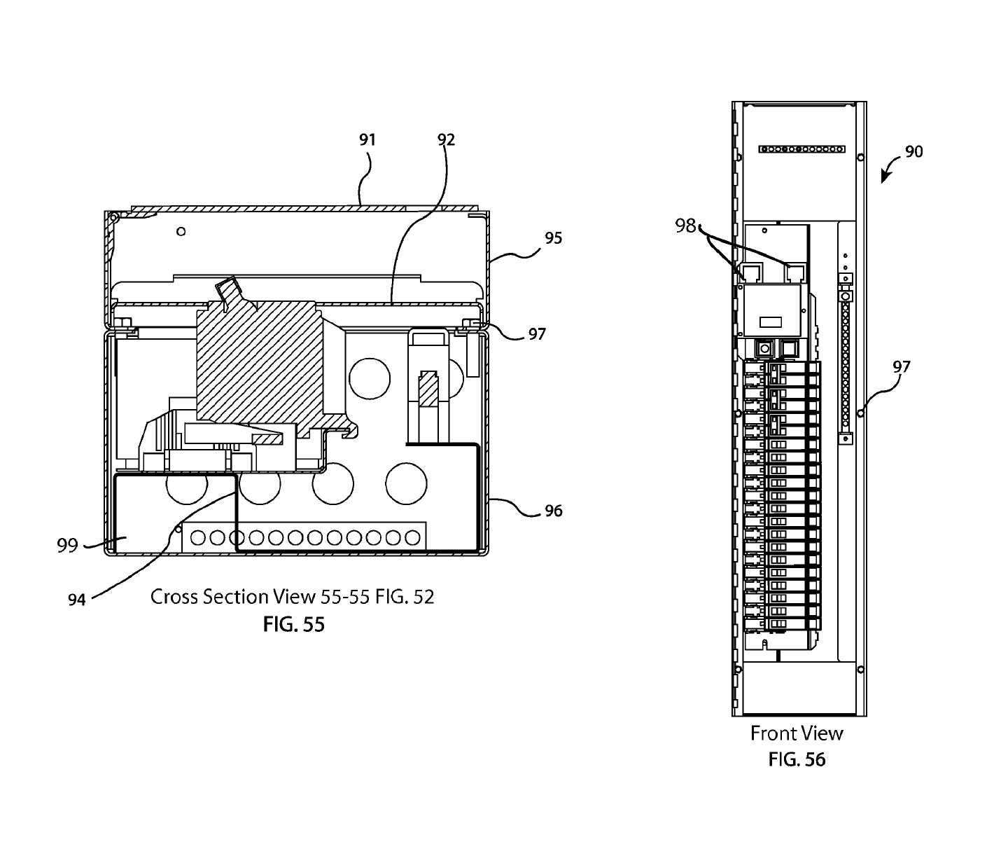

Referring now to FIGS. 52-56, an exemplary load center 90 that may be installed in the integrated electrical assembly 10 according to the present invention is shown. The load center 90 may include a load center door 91, which may be formed from a clear plastic, a load center panel cover 92, a panel 94, a load center housing 96 and lugs 98 for connecting the panel 94 to electrical wiring 7190 (FIGS. 71 and 72) that may be connected to electrical assembly power distribution block 83 of the main electrical feed unit 80. The electrical wiring 7190, shown in simplified form in FIGS. 71 and 72, may be pre-wired to the lugs 98 of the load center 90 so that all that is required during installation of the load center 90 and/or integrated electrical assembly 10 is connection of the wiring 7190 to the electrical assembly power distribution block 83. However, it is understood that such wiring 7190 may also be preconnected to the electrical assembly power distribution block 83 prior to installation of the integrated electrical assembly 10. Thus all feed risers are pre-wired in the factory, thereby reducing installation time on site. The panel 94 may include typical components found on an electrical panel, such as a supplemental or primary main disconnect, breakers, surge protection devices, grounding bars and neutral bars. In addition to including the typical components, the panel 94 may also be formed in such a manner so as to provide for a wire channel 99 within the load center 90 for at least the wiring 7190 (FIGS. 71 and 72). Referring still to FIGS. 52-56, the load center 90 may also include current transformers or other current monitoring devices on the main feeds and/or on one or more circuits protected by circuit breakers to monitor electrical usage. This may allow for users to review information regarding energy usage, and conserve energy as a result. Furthermore, demand sensing control devices may also be included in order to limit and/or control energy usage. The load center housing 96, panel 94 and load center panel cover 92 are configured to be installed and secured to the load center housing collar 95 by one or more fasteners 97. The fasteners 97 may be preinstalled on the load center housing 96, and then the head of the fasteners 97 may be positioned within tapered openings 93 of the load center housing collar 95 and then the fasteners 97 may be tightened in order to secure the load center housing 96 to the load center housing collar 95. Since the load center housing 96 and the panel 94 may be prewired with the appropriate wiring for the building structure and/or individual unit in which the load center 90 will be installed, it is understood that all that is required is for the load center housing 96 to be installed to the load center housing collar 95 in the manner discussed above, and the appropriate connections made between the wiring of the panel 94 to the electrical systems of the building structure and/or individual unit within the building structure. This exemplary design allows for labor related cost savings since much of the required wiring will have been connected in a controlled factory environment. As shown in FIG. 72, wiring from the load center 90 may be connected to the low voltage power supply unit 60 and/or loads of the individual unit, for example outlets, lighting, appliances, etc. The loads of the individual unit may be connected to the load center 90 either through cable connectors 32 or through hard-wired connections 7205. For example, the cable connectors 32 may be for pre-wired circuits of the individual unit having certain Amp ratings, e.g. 20 Amps or less and the hard-wired connections 7205 may allow for greater Amp ratings, e.g. 20 Amps or more. The connections may be made to one or more junction boxes 5001 that supply the loads of the individual unit. The junction boxes 5001 may be prewired in the walls of the individual unit prior to construction of the building structure. Since the load center 90 may be prewired to connectors 32 that are used to make connections to at least some of the loads of the individual unit, the load center 90 can be efficiently installed and/or removed from the integrated electrical assembly 10.

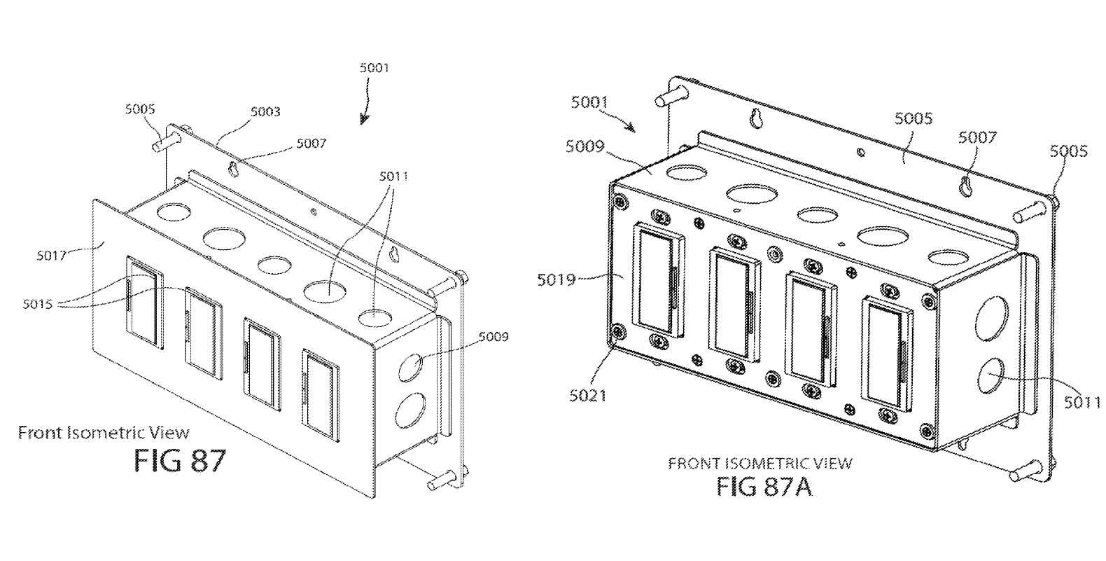

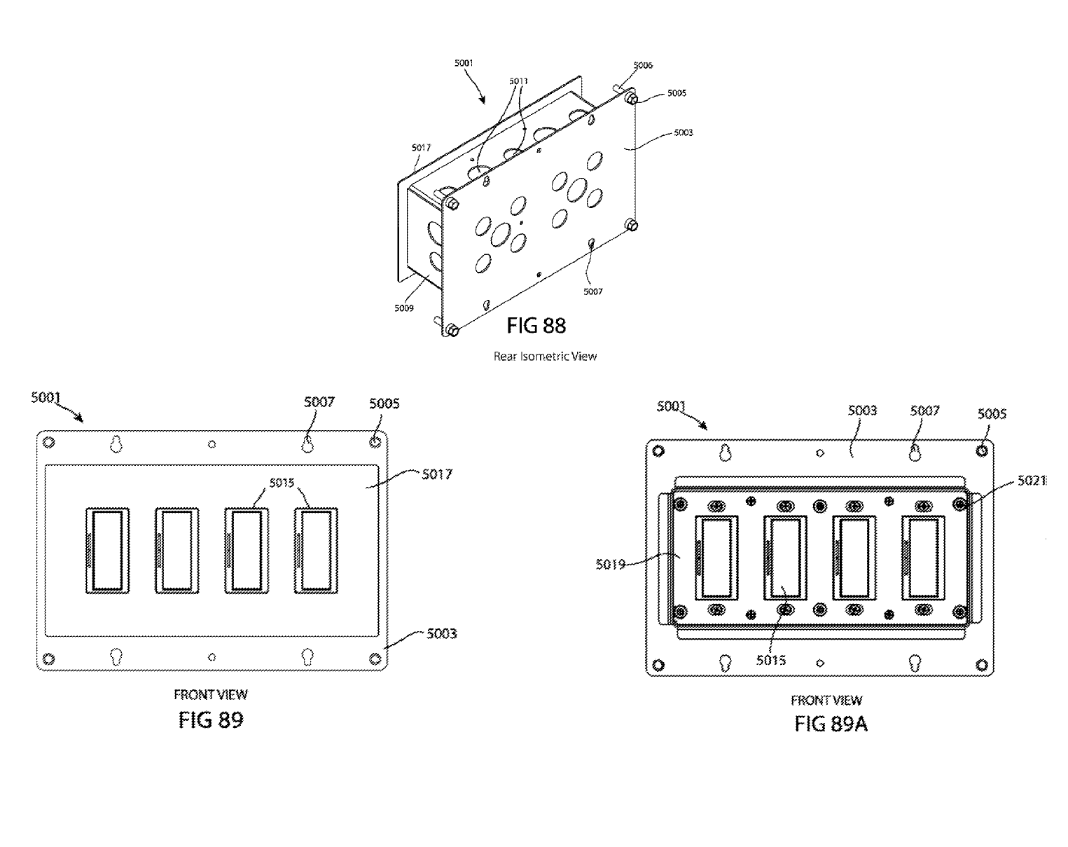

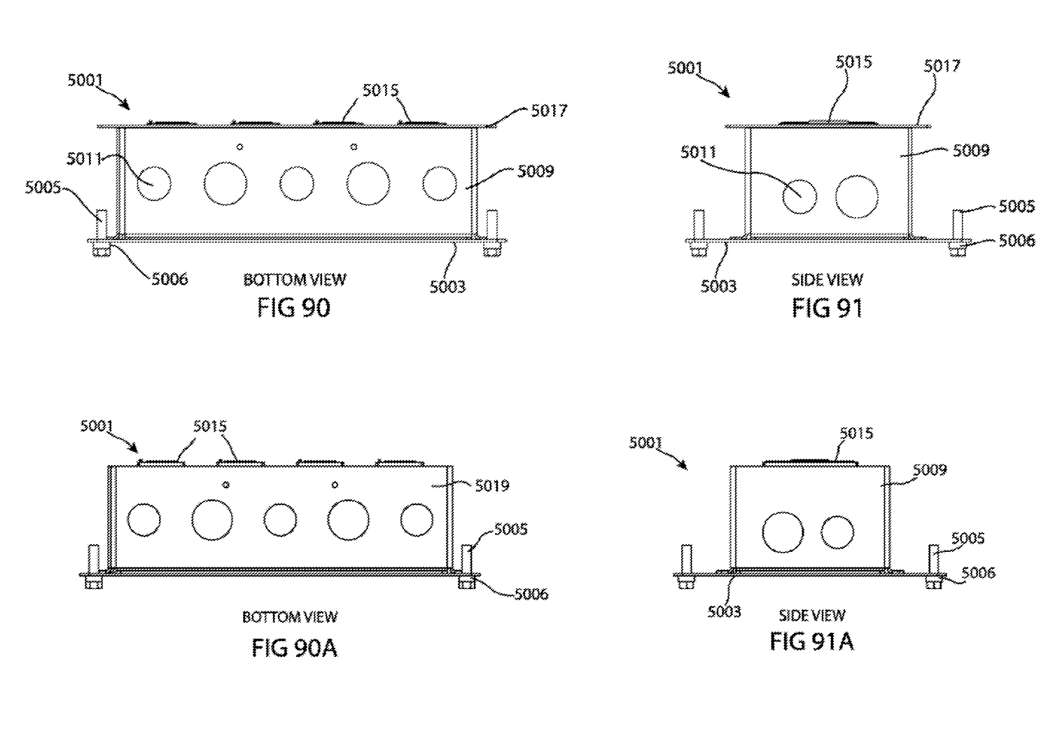

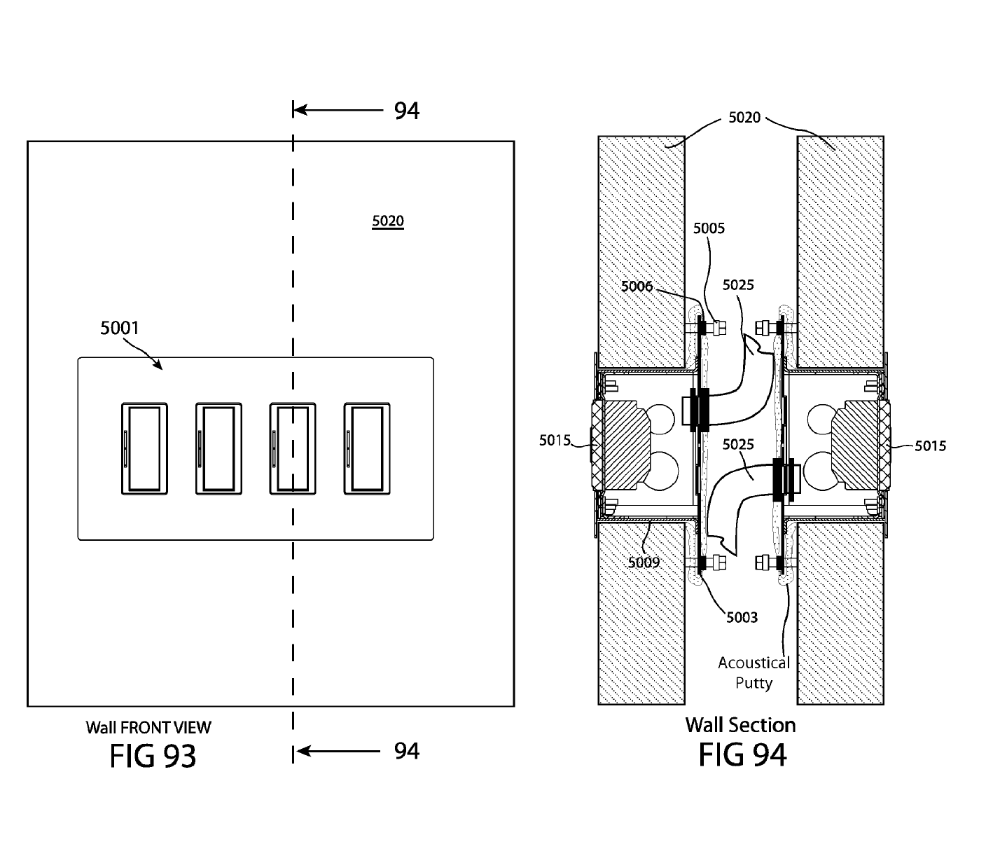

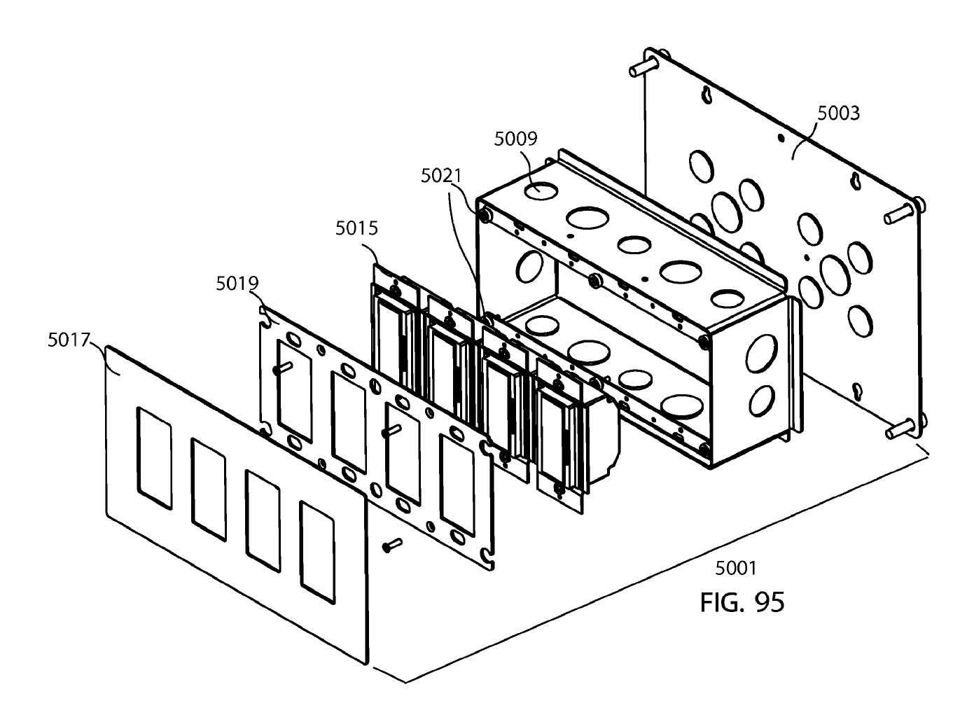

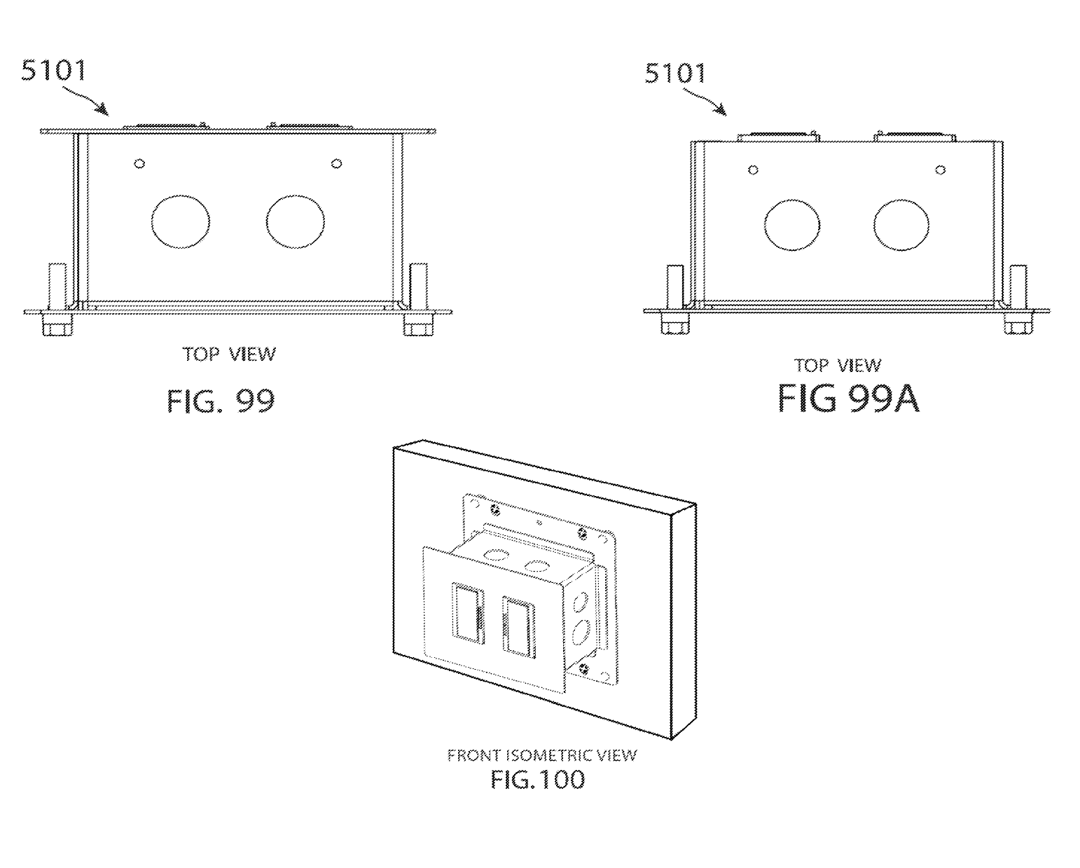

Exemplary junction boxes 5001 and 5101 that may be used with the integrated electrical assembly 10 are shown in detail in FIGS. 87-99, 87A-91A and 96A-99A. Referring to FIGS. 87-91 and 95, the junction box 5001 may include a back panel 5003 with at least four threaded adjustment lug 5006, a body 5009, at least one switch 5015, an interior cover 5019 configured to secure to the body 5009 so as to cover the components housed within the junction box 5001 and a decorative cover 5017 that may be configured to magnetically attach to the junction box 5001 by at least one magnet 5021. The magnet 5021 may preferably be a rare-earth magnet, such as a neodymium magnet. The at least one switch 5015 may also be other electrical components commonly found in junction boxes, such as outlets. The back panel 5003 and/or the body 5009 of the junction box 5001 may include one or more knock-outs 5011, and the back panel 5003 and the body 5009 may be secured to each other by suitable welding techniques. Referring now to FIGS. 89A-91A and 95, the decorative cover 5017 of the junction box 5001 may be removably secured to the junction box 5001 by one or more of the magnets 5021. As shown in FIGS. 89A-91A, even when the decorative cover 5017 is removed from the junction box 5001, the interior of the junction box 5001 is still covered by the interior cover 5019 so that the components therein are not exposed and thus the junction box 5001 without the decorative cover 5017 is configured for UL listing.

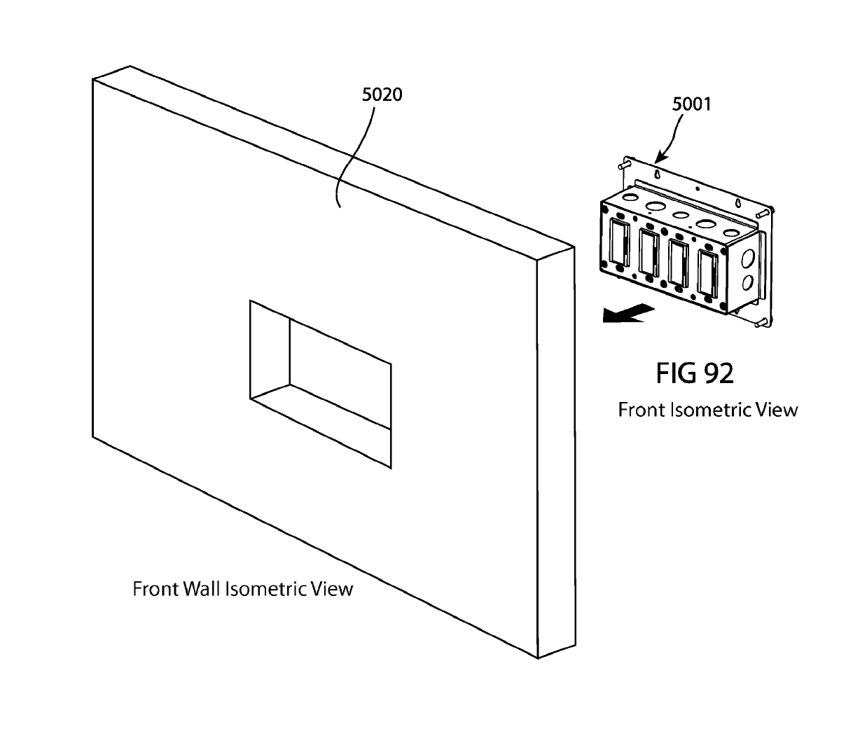

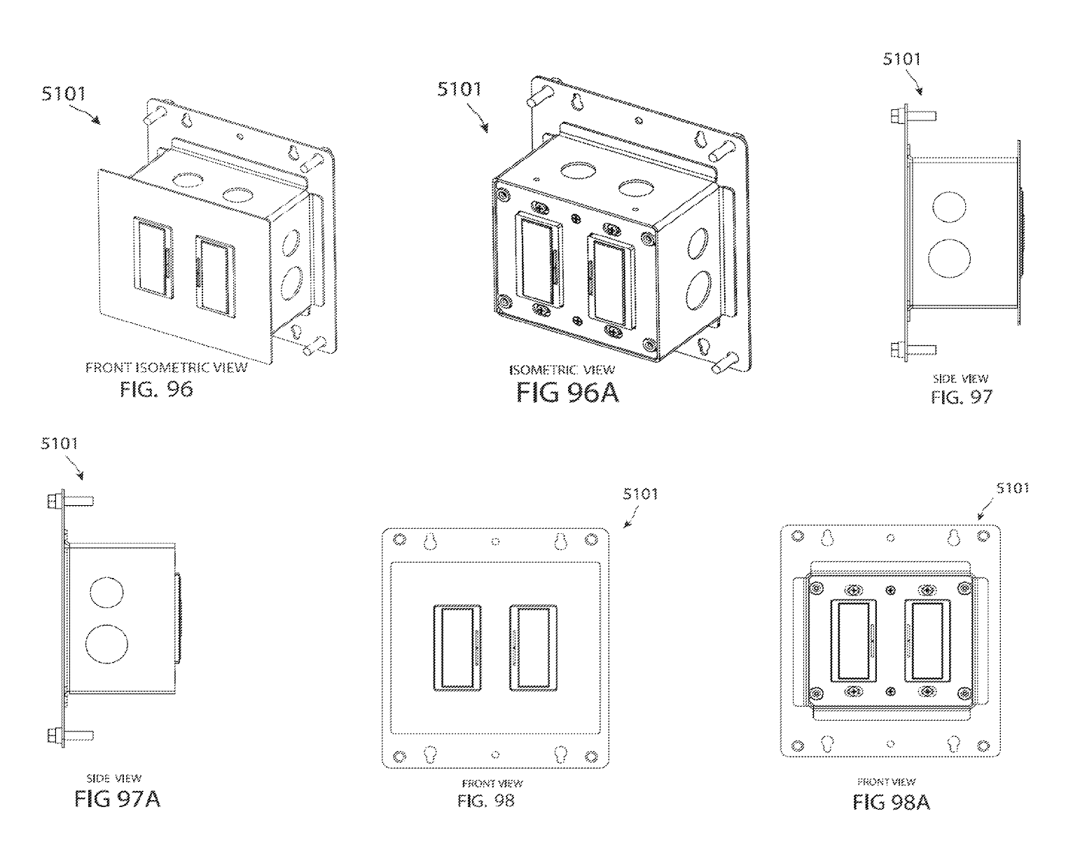

Referring now to FIGS. 92-94, the installation and adjustment of the junction box 5001 on an exemplary wall 5020 will now be discussed. As shown for example in FIG. 92, the junction box 5001 may be configured for installation from the back surface of the wall 5020. This exemplary design allows for simple cut-out in wall 5020, to be pre-wired and NRLT listed in a controlled factory environment, to be secured from rear of each junction box 5001, depth adjusted and acoustically sealed. In order to provide the junction box 5001 at the appropriate depth so that the decorative cover 5017 may be flushly secured to the junction box 5001 against the wall 5020. In order to adjust the junction box 5001 to the appropriate depth within the wall 5020, the tightening or loosening of the adjustment posts 5005 will cause the back panel 5003 to be pulled closer or pushed farther away from the wall 5020 as a result of the operative engagement between the adjustment posts 5005 and the threaded adjustment lugs 5006 on the back panel 5003. This configuration allows for adjustment and leveling of the junction box 5001 within the wall 5020. Then the junction box 5001 is secured to the wall 5020 by one or more fasteners 5027 placed through the slotted openings 5007 of the back panel 5003. A bead of acoustical putty 5023 may be placed between the back panel 5003 of the junction box 5001 and the wall 5020, and a layer of the acoustical putty 5023 may also be placed over the back panel 5003 of the junction box 5001 in order to reduce noise transfer through the junction box 5001. Once the junction box 5001 has been adjusted so that it is flush with the wall 5020, the decorative cover 5017 can be applied through use of the magnets 5021. In the event that additional materials and or decorations are added or removed from the walls, the junction box 5001 can be adjusted through the use of the adjustment posts 5005 and threaded adjustment lugs 5006. Furthermore, since the decorative cover 5017 is merely secured by magnets, wall treatments and/or wall panels placed on the wall 5020 can be efficiently and easily moved by simply removing and replacing the decorative cover 5017 on the junction box 5001. Referring particularly to FIG. 94, the knock-outs 5011 of the junction box 5001 may be positioned on the back panel 5003 and/or body 5009 so as to allow conduit 5025 running into and out of the junction box 5001 to be placed on the same plane so that the space required between walls 5020 to accommodate conduit from separate junction boxes 5001 is reduced. Referring now to FIGS. 96-99 and 96A-99A, therein illustrated is another exemplary embodiment of a junction box, generally indicated by reference numeral 5101 according to the present invention. The junction box 5101 contains the same construction, features and functionality as the junction box 5001 discussed above, but is configured in a 2-gang configuration. However, it is understood that the junction box according to the present invention may include any number of gangs as required for its application. FIG. 100 shows an alternative mounting configuration for the junction box 5101 in which the junction box 5101 may be surface mounted to the wall 5020.

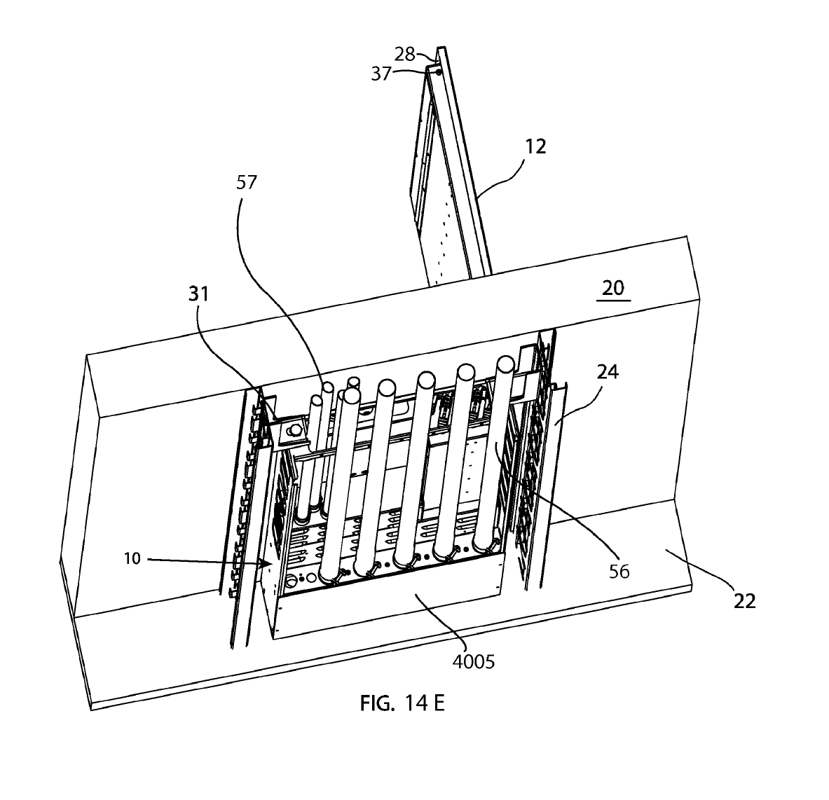

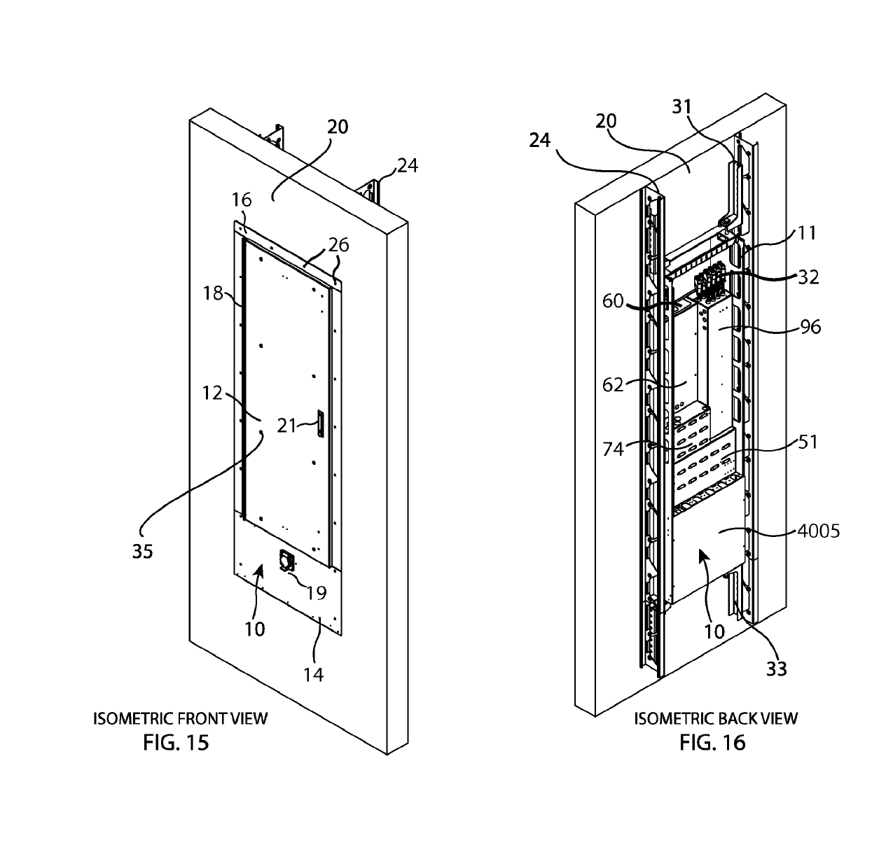

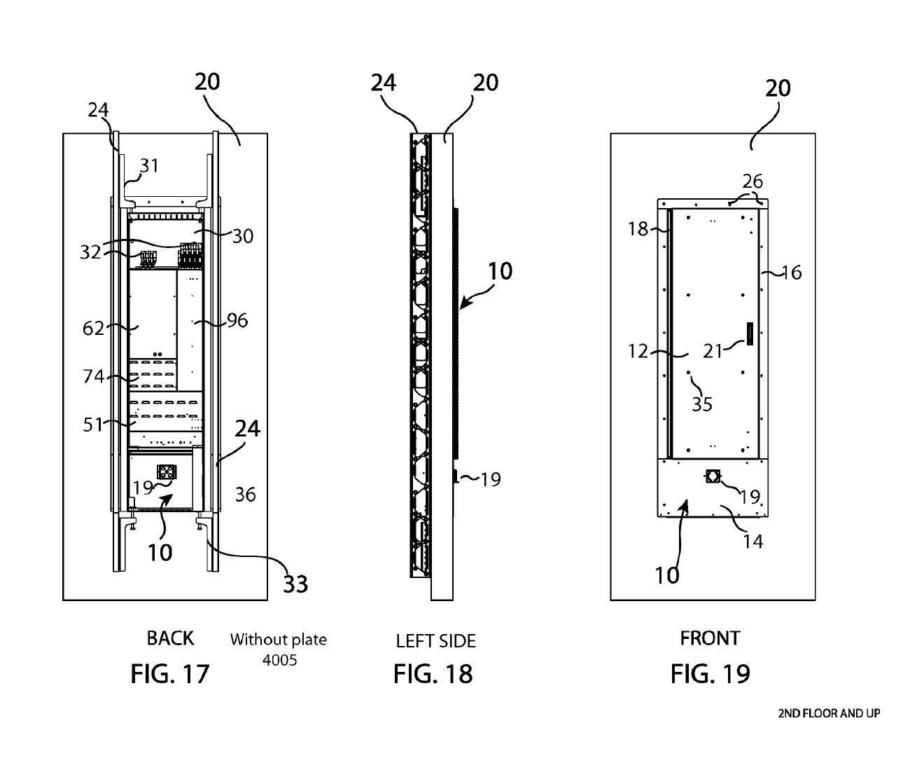

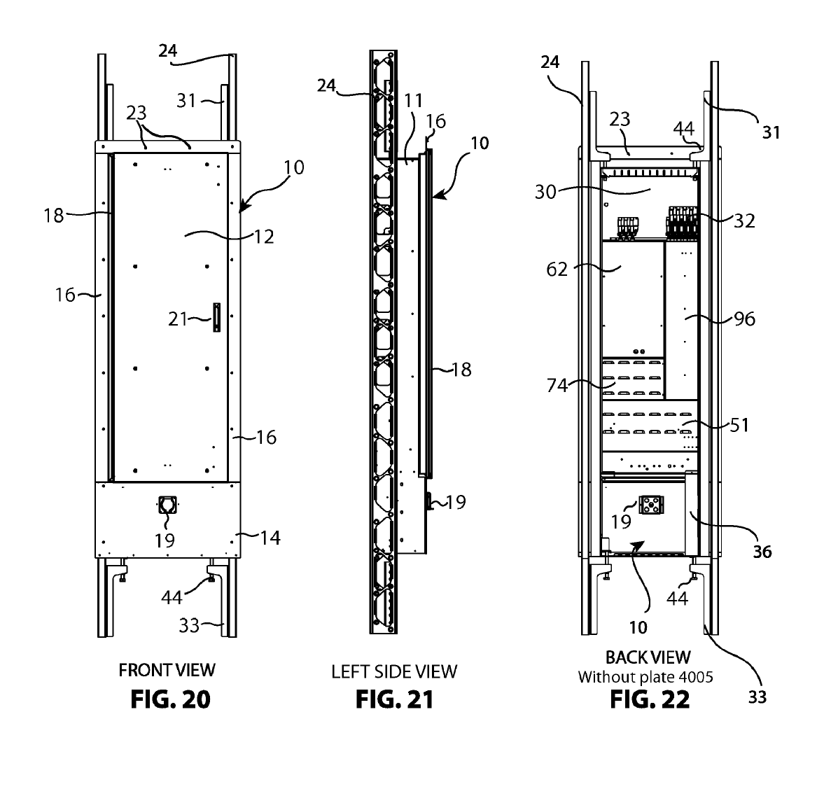

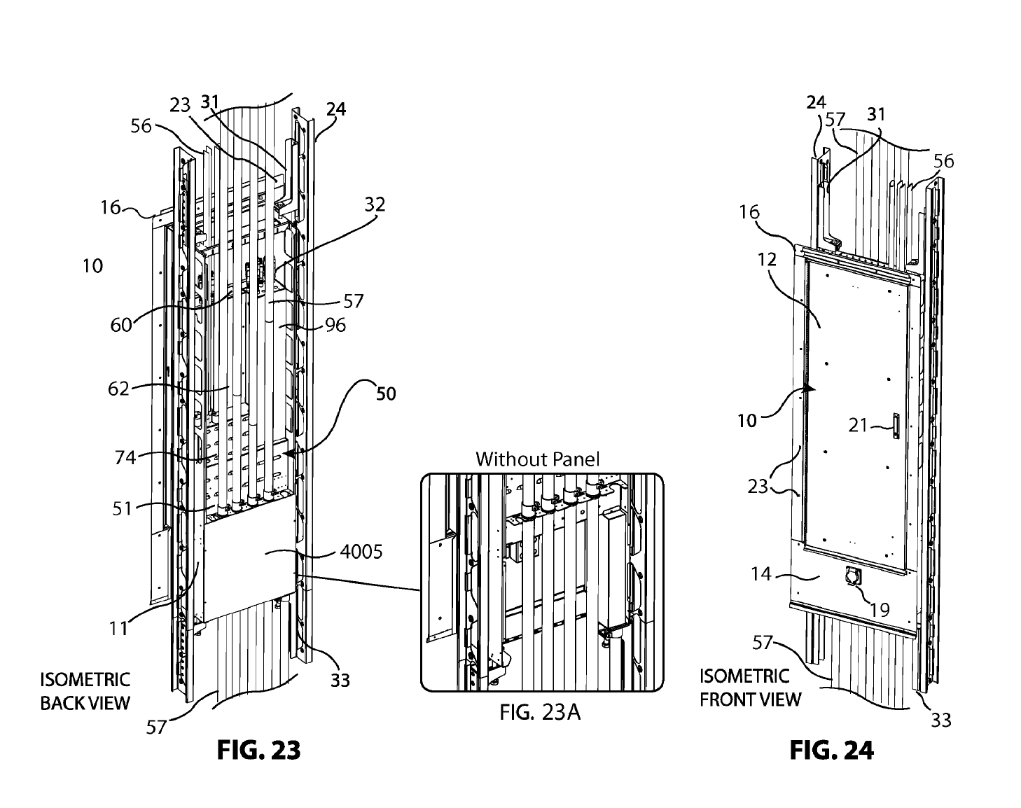

Referring now to FIGS. 15-24, an alternative use for the integrated electrical assembly 10 is shown in which the integrated electrical assembly 10 is installed on a wall above the floor and/or ground level. The integrated electrical assembly 10 may be installed in such a configuration through use of additional support brackets 33 positioned on the bottom of the integrated electrical assembly 10. The additional support brackets 33 are similar to the support brackets 31 in that they allow the integrated electrical assembly 10 to be secured to the wall supports 24 while allowing for adjustment, for example leveling, of the integrated electrical assembly 10. The integrated electrical assembly 10 may also include a removable cover 36 for a conductor compartment for running wiring to additional floors. It is understood that the integrated electrical assembly 10 shown in FIGS. 15-24 may include all of the same components and features of the integrated electrical assemblies discussed above. The access cover 4005 has been removed in FIGS. 17 and 22 for clarity. It is further understood that the integrated electrical assembly 10 may be configured so as to provide an inherently protected type IC NRTL listing that requires zero clearance to combustible materials for installation in wood stud walls and clothing closets with clothes in direct contact with the enclosures.

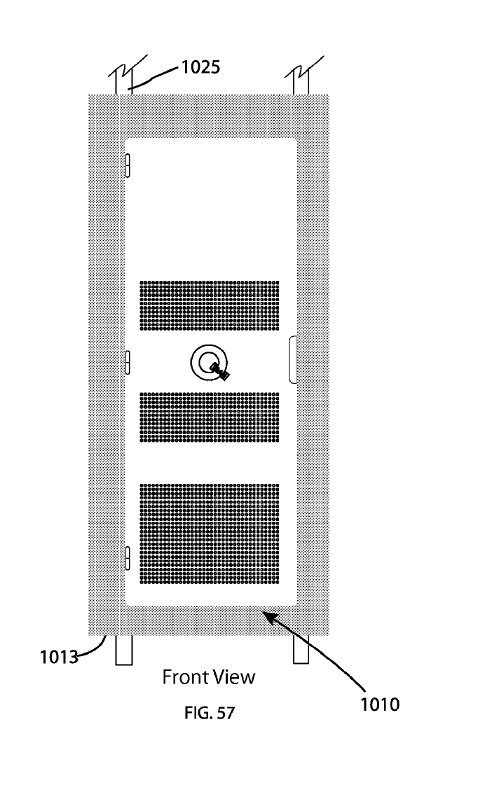

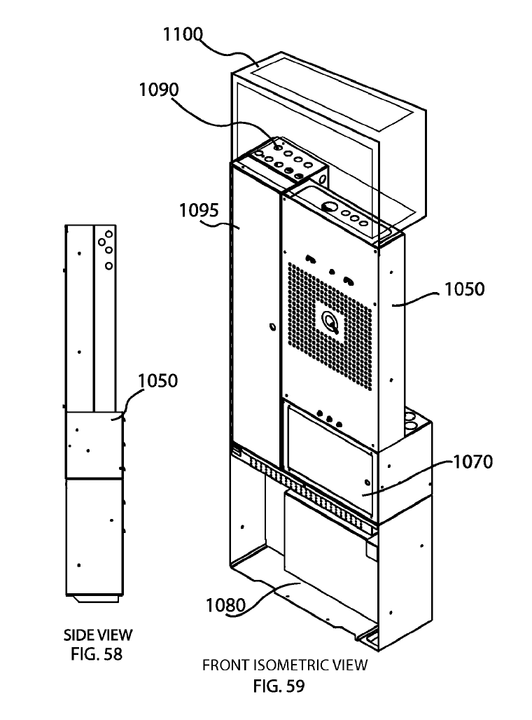

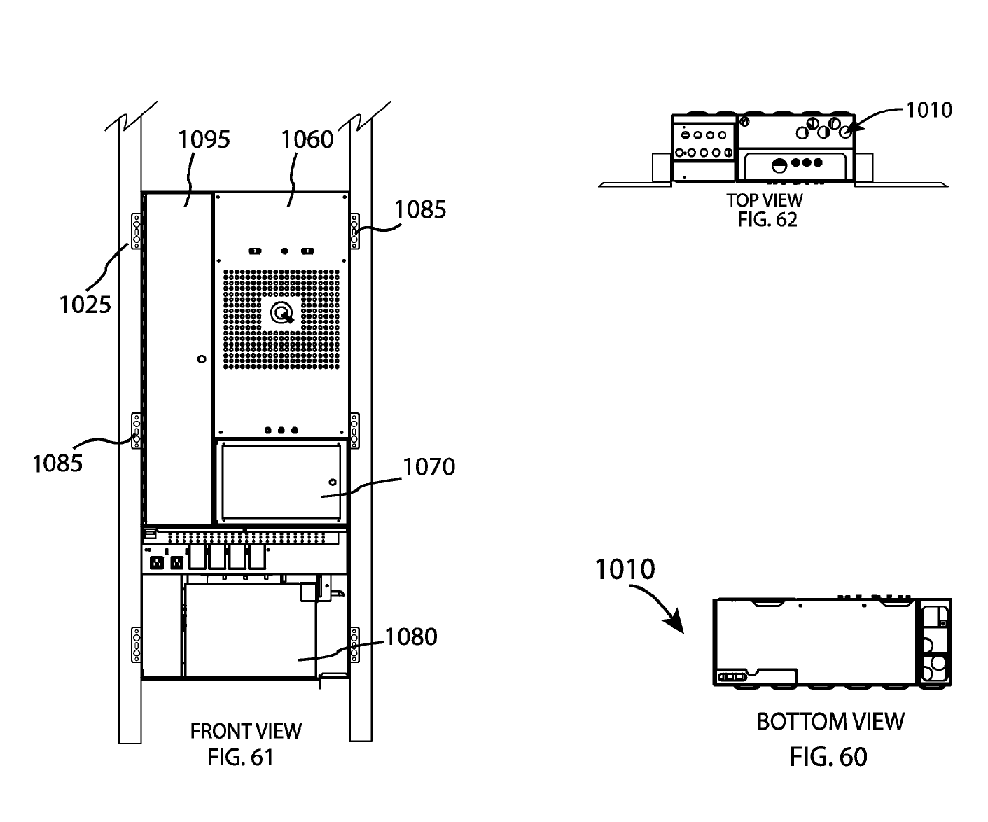

Now referring to FIGS. 57-62, therein illustrated is another exemplary embodiment of an integrated electrical assembly, generally indicated by reference numeral 1010, according to the present invention. The integrated electrical assembly 1010 may be configured for installation in a dry location, for example an indoor location, and may include a ventilated door 1013. The integrated electrical assembly 1010 may be installed to structural members 1025 of a wall, for example wood or steel stud framing, or other structure by mounting brackets 1085. The integrated electrical assembly 1010 may include a master tub 1050 configured to contain one or more components of the integrated electrical assembly 1010. The components that may be included in the integrated electrical assembly 1010 include, but are not limited to, a low voltage power supply unit 1060, a data-com component 1070, an alternative power unit 1080 and a load center 1090. The integrated electrical assembly 1010 may also include an access panel 1100 positioned so as to allow accessibility to the wiring and other parts of the components that may be connected to other integrated electrical assemblies and or building systems. It is understood that the integrated electrical assembly 1010 and components thereof contain substantially the similar parts and construction as discussed above with respect to the integrated electrical assembly 10, however it is understood that he integrated electrical assembly 1010 may include less components then the integrated electrical assembly 10 due to its suitability for dry location use. For example, the integrated electrical assembly 1010 may not include a door and/or a frame as included in integrated electrical assembly 10. It is further understood that the integrated electrical assembly 1010 may be configured so as to provide an inherently protected type IC NRTL listing that requires zero clearance to combustible materials for installation in wood stud walls and clothing closets with clothes in direct contact with the enclosures.

It is understood that the integrated electrical assemblies and components thereof are not limited to any particular material and/or construction, but it is preferable that the integrated electrical assemblies be constructed of substantially durable materials to suit their intended purposes. It may also be preferable that the materials used to form or manufacture the integrated electrical assemblies and components thereof be treated and prepared so as to resist corrosion or physical damage, for example by preparation through suitable powder-coating techniques. Preferably, the frame 11 and swing door 12 of the integrated electrical assembly 10 may be formed from galvannealed steel with a powder-coating sufficient to obtain a NEMA X rating for salt spray, such as a NEMA 4X rating.

It will thus be seen that the objects set forth above, among those made apparent from the preceding description, are efficiently attained and, since certain changes may be made in the above article without departing from the scope of this invention, it is intended that all matter contained in this disclosure or shown in the accompanying drawings, shall be interpreted, as illustrative and not in a limiting sense. It is to be understood that all of the present figures, and the accompanying narrative discussions of corresponding embodiments, do not purport to be completely rigorous treatments of the invention under consideration. It is to be understood that the above-described arrangements are only illustrative of the application of the principles of the present invention. Numerous modifications and alternative arrangements may be devised by those skilled in the art without departing from the scope of the present invention.

What is claimed is:

1. A multi-wire connector, comprising:
a terminal block including a plurality of set screws, wherein the plurality of set screws are configured to be loosened and tightened relative to the terminal block;
a housing configured to contain the terminal block, wherein the housing includes vents along an upper edge and along a lower edge, the vents configured to provide ventilation for the terminal block.

2. The multi-wire connector of claim 1, wherein the terminal block includes grooves along an inner surface.

3. The multi-wire connector of claim 1, further comprising a set screw cover positioned over at least one of the plurality of screws coupled to the housing.

4. The multi-wire connector of claim 3, wherein the set screw cover includes a vent.

5. The multi-wire connector of claim 1, wherein at least one of the plurality of set screws includes a color coded plug.

6. The multi-wire connector of claim 1, wherein the housing is configured to be secured to a base mount.

7. The multi-wire connector of claim 6, wherein the housing further includes two mounting tabs below the terminal block, wherein the two mounting tabs are configured to couple to a lock and release tab on the base mount.

8. The multi-wire connector of claim 6, wherein the base mount is secured to a surface by a fastener.

9. The multi-wire connector of claim 6, wherein the base mount is configured to couple to a plurality of housings.
